(19) United States
(12) Patent Application Publication
(10) Pub. No.: US 2023/0282837 A1
(43) Pub. Date: Sep. 7, 2023

(54) METAL CONDUCTING COATINGS FOR ANODES, METHODS OF MAKING AND USING SAME, AND USES THEREOF

(71) Applicant: CORNELL UNIVERSITY, Ithaca, NY (US)

(72) Inventors: Lynden A. Archer, Ithaca, NY (US); Jingxu Zheng, Shenzen (CN); Jiefu Yin, Ithaca, NY (US)

(21) Appl. No.: 18/008,384

(22) PCT Filed: Jun. 7, 2021
(86) PCT No.: PCT/US2021/036242

§ 371 Date: Dec. 5, 2022

Related U.S. Application Data
(60) Provisional application No. 63/035,798, filed on Jun. 7, 2020.

(51) Int. Cl. H01M 4/62; H01M 4/04; C25D 5/04; C25B 11/069; C30B 7/12; C30B 7/00; C30B 29/02; H01G 11/30

(52) U.S. Cl. CPC H01M 4/626; H01M 4/0452; C25D 5/04; C25B 11/069; C30B 7/12; C30B 7/005; C30B 29/02; H01G 11/30; H01M 2004/027

(57) ABSTRACT

In various examples, an anode, which may be for a metal ion-conducting electrochemical device, comprises a metal member; and a metal conducting coating, which may be an epitaxial (e.g., a homoepitaxial) metal conducing coating, disposed on at least a portion of the metal member (e.g., all portions of the metal member that would be or are in contact with the electrolyte of the metal ion-conducting electrochemical device). A metal conducting coating or an anode may be formed by electrodeposition in the presence of a field.

### CROSS-REFERENCE TO RELATED APPLICATIONS

This application claims priority to U.S. Provisional Patent Application No. 63/035,798, filed Jun. 7, 2020, the disclosure of which is incorporated in its entirety herein by reference.

### STATEMENT REGARDING FEDERALLY SPONSORED RESEARCH

This invention was made with government support under contract nos. DE-SC0012673 and DE-SC0016082 awarded by the Department of Energy and contract no. 1719875 awarded by the National Science Foundation. The government has certain rights in the invention.

### BACKGROUND OF THE DISCLOSURE

Morphological evolution during formation of a crystalline, solid phase from a liquid solution is of scientific and practical interest in fields ranging from protein drug formulation, particle science, to metallurgy. Depending upon the conditions at which the phase transformation occur, it is possible to interrogate both equilibrium and non-equilibrium phenomena associated with solid phase nucleation and growth.

It is known that successful application of electrodeposition to create conformal coatings in, for example, metal anodes or where the metal anode is formed spontaneously on a charged insertion electrode requires fast transport of charged species (e.g., ions, particles, polymers) in an electrolyte medium and stable redox reactions and transport at the electrolyte/electrode interface at which the deposition occurs. The propensity of metals to violate these requirements and to deposit on planar and non-planar substrates in rough, non-planar morphologies has been actively studied since the discovery of electroplating in the 1800s. It has been shown that multiple factors, including temperature, properties of electrolyte substrate chemistry/geometry, etc. and their interplay could exacerbate or mitigate this propensity. The problem has reemerged as a priority research direction in recent years because of the role rough, dendritic electrodeposition of metals plays in premature failure and short-circuiting of high-capacity metallic battery anodes. The concomitant interest in batteries that utilize thin metal electrodes to minimize system weight & cost, motivates a complimentary need for electrochemical manufacturing approaches able to create thin (<50 μm), compact metal or metal alloy coatings on electrically conducting substrates. Classical transport theory predicts that the growth and proliferation of such dendrites are the result of a combination of morphological and hydrodynamic instabilities, which lead to complex interfacial transport behaviors, including formation of localized concentration of electric field lines in regions of an electrode, which at all currents produce bursts of localized metal deposition and growth to form porous or mossy metal deposits. At currents above the diffusion limit, the process also drives development of an ion depleted Extended Space Charge Layer (ESCL) near any ion selective interphase in an electrolyte and to the nucleation and rapid growth of diffusion-limited, classical tree-like structures termed dendrites. Porous, mossy, or dendritic electrodeposition is fundamentally unsuitable in the battery context because once formed at a battery anode, the deposits grow aggressively to form high surface area structures that consume electrolyte components, fill the inter-electrode space, short-circuiting the battery, or which may break away from the conductive substrate (current collector) to electrically isolate the metal deposit—reducing the efficiency of active material use in the electrode.

A large body of work already exists which shows that, consistent with classical transport theory, conformal electrodeposition of many metals (e.g., Zn, Cu, Sn, and Ag) at planar electrodes can be sustained only at current densities below a diffusion-limited critical value

$${i}_{L} = \frac{4 F {C}_{0} D}{L}$$

and/or at voltages below the predicted threshold V<V_{cr}≈8 RT/F for the onset of hydrodynamic instability termed electroconvection. Here C₀ is the salt concentration in the electrolyte, RT/F=kT/e is the thermal voltage, D is the diffusivity and L is the interelectrode spacing. Electrodeposition under conditions outside these bounds has likewise been reported to produce non-planar, classically dendritic (tree-like) morphologies. Nonetheless, the vast majority of these reports focus on dilute electrolytes (e.g., C₀<0.1 M) with supporting salts. The concentrations are well below typical electrolyte concentration employed in battery cells (e.g., C₀≥1 M). In contrast, electrodeposition of many of the most important metals (e.g., Li, Na, Al, Pb, and Zn) in the batteries context are typically studied in moderately salty electrolytes (e.g., C₀≥1M) and broadly found to exhibit the following non-classical attributes: (i) formation of low-density mossy or wire/whisker like non-planar electrodeposition morphologies, as opposed to classical tree-like dendrites; (ii) a transition from planar to non-planar electrodeposit structure under far milder conditions (e.g., i<<i_{L} and V<<V_{cr}) than predicted by classical theory; (iii) poor reversibility of the formed metallic deposits.

### SUMMARY OF THE DISCLOSURE

In an aspect, the present disclosure provides metal conducting coatings. The metal conducting coatings may be used for reversible metal anodes. The metal coatings may be epitaxial conducting coatings (e.g., have a desirable amount of lattice mismatch with an electrodeposited metal layer formed during operation (e.g., metal plating, which may be during recharge of an electrochemical device, such as, for example, a secondary battery) of an electrochemical device. The metal conducting coating may be alternatively referred to as a base layer. In various examples, a metal conducting coating is formed by a method of the present disclosure. Metal conducting coatings may provide a surface that results in epitaxial (e.g., low lattice mismatch) electrodeposition of metal(s), which may be reversible, of the reduced form of the metal ions of metal-ion conducting electrochemical devices. In various examples, a metal conducting coating may be the same metal as or a different than the metal of the metal member and/or the metal conducting coating is the reduced form (i.e., metal form) of the metal-ions of the metal ion-conducting electrochemical device or a different metal than the reduced form (i.e., metal form) of the metal-ions of the metal ion-conducting electrochemical device. A metal conducting coating may be formed by electrodeposition.

In an aspect, the present disclosure provides anodes. An anode comprises one or more metal conducting coating(s) of the present disclosure. A portion or all of the metal conducting coatings may be epitaxial conducting coatings. The coatings may be used as a battery anode and may be a reversible anode. In various examples, one or more or all of metal conducting coating(s) is/are made by a method of the present disclosure. In various examples, the anode(s) are part of secondary batteries or secondary cells, which may be rechargeable batteries, or primary batteries or primary cells. An anode may promote epitaxial electrodeposition, which may be reversible, of the reduced form the metal-ions of an ion-conducting electrochemical device.

In an aspect, the present disclosure provides methods of making metal conducting coatings and anodes. A method may be used to make a metal conducting coating or an anode of the present disclosure. An at least partially aligned metal layer produced by a method of the present disclosure may be at least a portion of an anode. The methods may be in situ methods or ex situ methods. In various examples, a method of making a metal conducting coating (e.g., a metal conducting coating of the present disclosure) disposed on at least a portion of an exterior surface of a substrate comprises: electrodepositing a metal layer on at least a portion of an exterior surface of a substrate in the presence of a field. The electrodeposition results in a formation of a metal conducting coating (e.g., a metal conducting coating of the present disclosure) disposed on at least a portion of an exterior surface. A field may be a hydrodynamic field. A hydrodynamic field may be produced by applying a force to a preformed electrochemical device.

In an aspect, the present disclosure provides methods of operating an electrochemical device. The methods provide an electrochemically deposited layer of a metal formed by the reduction of the metal-ions of the metal-ion conducting electrochemical device. In various examples, during an epitaxial electrodeposition process at an anode of the present disclosure, which may be present in an electrochemical devices, such as, for example, a battery, an electrochemically inactive substrate with the right crystal symmetry and lattice parameters would, upon charging, facilitate the homoepitaxial or heteroepitaxial nucleation and growth of the electrochemically active metal in a strain-free or substantially strain-free state. In an example, an electrochemical device is under current flow and an electrochemically deposited layer of a metal formed by the reduction of the metal-ions of the metal-ion conducting electrochemical device is formed on at least a portion of the metal conducting coating of the electrochemical device. The electrochemically deposited layer may be reversibly formed.

### BRIEF DESCRIPTION OF THE FIGURES

For a fuller understanding of the nature and objects of the disclosure, reference should be made to the following detailed description taken in conjunction with the following figures.

FIGS. 1A-1B are illustrations showing proposed differences between electrodeposition morphology and ion concentration in dilute and concentrated electrolytes. (1A) Dendritic growth during metal deposition in dilute electrolyte solutions in the over-limiting transport regime. (1B) Crystallographic reorientation and growth during metal electrodeposition in concentrated electrolyte solutions above the diffusion limit.

FIGS. 2A-2E show electrochemical measurements of Zn electrodeposition. Current-voltage (i-V) curves of Zn electrodeposition on a glassy carbon electrode at a scan rate of 5 mV/s in: (2A) 2.5M (M=molar concentration), (2B) 0.5M and (2C) 0.05M ZnSO₄ (aq) electrolytes. Time-dependent current measured in constant-voltage, chronoamperometric Zn electrodeposition in the over-limiting transport regime: (2D) 2.5 M and (2E) 0.05 M ZnSO₄ (aq) electrolyte. For the results in (2D) the potential was held at −2.3 V and in (2E) at −1.9 V (V=volt(s)) vs. (AgCl/Ag).

FIGS. 3A-3H show scanning electron microscopy (SEM) images showing morphological evolution of Zn electrodeposits in a concentrated, 2.5 M ZnSO₄ (aq) electrolyte at different potentials: (3A-3B) −1.9 V, (3C-3D) −2.1V, (3E-3F) −2.3 V without rotation, and (3G-3H) −2.3V with 1000 rpm rotation. Deposition time 60 s (s=second(s)).

FIGS. 4A-4H show SEM images showing morphological evolution of Zn electrodeposits in a dilute, 0.05 M ZnSO₄ (aq), electrolyte at different potentials: (4A-4B) −1.3 V, (4C-4D) −1.6 V, (4E-4F) −1.9 V without rotation, and (4G-4H) −1.9 V with 1000 rpm rotation. Deposition time 60 s.

FIGS. 5A-5B show optical micrographs of Zn electrodeposits obtained in (5A) 0.05 M and (5B) 2.5 M ZnSO₄ electrolyte. The chronoamperometric electrodeposition was performed under over-limiting conditions (#3 and #7 in FIG. 1).

FIGS. 6A-6F show X-ray analysis of the crystallographic evolution of Zn during electrodeposition in a concentrated, 2.5 M ZnSO₄ (aq) electrolyte with and without normal flow. (6A) XRD line-scan patterns for the Zn electrodeposits. (6B) The peak intensity ratio of the Zn 002:101 deduced from the line scans in (6A). 2D-XRD patterns of Zn electrodeposited at: (6C) −1.9 V, (6D) −2.1V, (6E) −2.3 V without rotation, and (6F) −2.3V with 1000 rpm rotation.

FIGS. 7A-7D show electrochemical reversibility of Zn electrodeposits measured in a 2.5 M ZnSO₄ (aq) electrolyte. (7A) Coulombic efficiency for Zn plating/stripping with and without rotation. (7B) Coulombic efficiency for Zn plating/stripping at different RDE rotation rates. Time-dependent evolution of the current density during stripping of Zn deposited (7C) w/ and (7D) w/o normal flow.

FIG. 8 shows coulombic efficiency of Zn plating/stripping in 0.05 M ZnSO₄. The CE values achieved in 0.05 M (15%, 47% and 65%) are substantially lower than the ones in 2.5 M ZnSO₄ (80˜90%). As revealed by the SEM characterization, the electrodeposition morphology in 0.05 M electrolyte is highly dendritic. The results suggest that dendritic metal electrodeposits have a low plating/stripping reversibility, owing to morphological instability.

FIGS. 9A-9B show schematic diagram showing the stripping of (9A) porous, non-planar and (9B) compact, planar electrodeposits. The interface of the stripping process is indicated.

FIG. 10 shows an effect of electrodeposition overpotential on the average size of Zn plates deposited in a concentrated, 2.5M ZnSO₄ (aq) electrolyte. The dashed line through the points corresponds to the trivial scaling relationship Φₚₗₐₜₑ˜V.

FIGS. 11A-11B show electrochemical characteristics of Cu deposition on glassy carbon electrode from 1 M CuSO₄ electrolyte. (11A) Current-voltage (i-V) curves of Cu electrodeposition w/ and w/o rotation. (11B) Time-dependent current measured in constant-voltage, chronoamperometric Cu electrodeposition.

FIGS. 12A-12H show SEM images showing morphological evolution of Cu electrodeposits in a concentrated, 1 M CuSO₄ (aq) electrolyte at different potentials: (12A-12B) −0.4 V, (12C-12D) −1.0 V, (12E-12F) −1.6 V without rotation, and (12G-12H) −1.6V with 1000 rpm rotation. Potential referenced to AgCl/Ag electrode. Deposition time 120 s. As shown in the SEM images, the porosity of Cu electrodeposits as the overpotential increases. When a normal flow is introduced, the porosity is eliminated. Throughout the whole evolution, no branched dendritic pattern is observable.

FIGS. 13A-13B show electrochemical characteristics of Cu deposition on glassy carbon electrode from 0.05 M CuSO₄ electrolyte. (13A) Current-voltage (i-V) curves of Cu electrodeposition w/ and w/o rotation. (13B) Time-dependent current measured in constant-voltage, chronoamperometric Cu electrodeposition.

FIGS. 14A-14B show SEM images showing morphological evolution of Cu electrodeposits in a 0.05 M CuSO₄ (aq) electrolyte (14A-14B) −1.6 V without rotation. Branched, tree-like dendrites are observed.

FIGS. 15A-15B show electrochemical characteristics of Li deposition on glassy carbon electrode from 1 M LiPF₆ electrolyte. (15A) Current-voltage (i-V) curves of Li electrodeposition w/ and w/o rotation. (15B) Time-dependent current measured in constant-voltage, chronoamperometric Li electrodeposition.

FIGS. 16A-16F show SEM images showing morphological evolution of Li electrodeposits in a concentrated, 1 M LiPF₆ in carbonate-based electrolyte at different potentials: (16A-16B) −0.6 V, (16C-16D) −1.5 V, (16E-16F) −2.7 V without rotation. Potential referenced to Li⁺/Li electrode. Deposition time 120 s.

### DETAILED DESCRIPTION OF THE DISCLOSURE

Although claimed subject matter will be described in terms of certain examples, other examples, including examples that may not provide all of the benefits and features set forth herein, are also within the scope of this disclosure. Various structural, logical, and process step changes may be made without departing from the scope of the disclosure.

Ranges of values are disclosed herein. The ranges set out a lower limit value and an upper limit value. Unless otherwise stated, the ranges include the lower limit value, the upper limit value, and all values between the lower limit value and the upper limit value, including, but not limited to, all values to the magnitude of the smallest value (either the lower limit value or the upper limit value) of a range.

The present disclosure provides metal conducting coatings. The present disclosure also provides metal anodes comprising one or more of the metal conducting coating(s) and devices comprising one or more of the metal conducting coating(s) and/or one or more of the metal anode(s). The present disclosure also provides methods of making metal conducting coatings and anodes and devices.

In an aspect, the present disclosure provides metal conducting coatings (the metal conducting coatings may be alternatively referred to as metal conductive coatings, conducting coatings, or substrates). The coatings may be used as a battery anode and may be a reversible anode. The metal coatings may be epitaxial conducting coatings (e.g., have a desirable amount of lattice mismatch with an electrodeposited metal layer formed during operation (e.g., metal plating, which may be during recharge of an electrochemical device, such as, for example, a secondary battery) of an electrochemical device. Lattice mismatch may also be alternatively referred to as lattice misfit. The metal conducting coating may be alternatively referred to as a base layer. Non-limiting examples of metal conducting coatings are provided herein. In various examples, a metal conducting coating is formed by a method of the present disclosure.

Metal conducting coatings may provide a surface that results in epitaxial (e.g., low lattice mismatch) electrodeposition of metal(s), which may be reversible, of the reduced form of the metal ions of metal-ion conducting electrochemical devices. Without intending to be bound by any particular theory, it is considered that the metal conducting coatings promote epitaxial (e.g., low lattice mismatch) electrodeposition of the reduced form of the metal ions of metal-ion conducting electrochemical devices. In various examples, the metal of the metal conducting coating has the same or similar crystal structures to those observed in the bulk (e.g., plated) metal. As an illustrative example, a metal conducting coating provides a surface that results in epitaxial (e.g., low lattice mismatch) electrodeposition, which may be reversible, of lithium metal of a lithium-ion conducting electrochemical device (e.g., a lithium-ion conducting battery such as, for example, a primary or secondary lithium-ion conducting battery).

It may be desirable that a metal conducting coating results in epitaxial electrodeposition, which may be reversible, of a metal. It may be desirable that a metal conducting coating is conductive (e.g., able to conduct electrons or the like) so that the electrochemical deposition can occur. In certain examples, the metal conducting coating is textured, preferentially exposing certain crystal facets. Without intending to be bound by any particular theory, it is considered that when the lattice misfit between the metal conducting coating and the metal (e.g., bulk metal) is low, the epitaxial effect is strong.

A metal conducting coating may promote epitaxial electrodeposition, which may be reversible, of the reduced form the metal-ions of an ion-conducting electrochemical device. For example, epitaxial electrodeposition is provided by a metal conducting coating that has 20% or less lattice mismatch (e.g., 10% or less, 5% or less, 4% or less, 3% or less, 2% or less, or 1% or less), with the reduced form (i.e., metal form) of the metal-ions of the metal ion-conducting electrochemical device. When the lattice mismatch is greater than 20%, the epitaxial electrodeposition may also occur on a textured metal conducting coating, which may have exposed a particular (e.g. oriented) crystal facet or plane), in which a certain crystal facet may be exposed (e.g., a close packed plane, such as, for example, a (001) plane in hexagonal close packed structures, a (111) plane in face centered cubic structures, (110) plane in body centered cubic structures, and the like).

A metal conducting coating may exhibit a desirable amount of lattice strain (particularly, with regard to the first metal layer deposited on the metal conducting coating) and/or lattice mismatch. Epitaxial growth of films of metal layer may be based on specific interface structures between the crystal lattices of the layer (aₑₚᵢ), which would be the metal layer (e.g., the reduced form of the metal ions of the metal-ion conducting electrochemical device) formed on the epitaxial conducting coating, and substrate (a_{sub}), which refers to the epitaxial conducting coating. These interfaces may be characterized by the lattice mismatch, which may be defined as f where

$$f = \frac{{α}_{sub} - {α}_{epi}}{{α}_{sub}}$$

The metal conducting coating may have a 20% or less lattice mismatch (e.g., 10% or less, 5% or less, 4% or less, 3% or less, 2% or less, or 1% or less), which may be f with the reduced form (i.e., metal form) of the metal-ions of the metal ion-conducting electrochemical device. The metal conducting coating may have a 20% or less lattice mismatch (e.g., 10% or less, 5% or less, 4% or less, 3% or less, 2% or less, or 1% or less), which may be f with the reduced form (i.e., metal form) of the metal-ions of the metal ion-conducting electrochemical device having, for example, a close packed plane, such as, for example, a (002) plane in hexagonal close packed structures, a (111) plane in face centered cubic structures, (110) plane in body centered cubic structures, and the like).

A metal conducting coating may have various textures. The electrodeposits in general show a preference for exposing the crystal planes that have high packing density, e.g., the close-pack plane. The “texturing” describes a process in which the electrodeposits tend to align their close-packed basal plane horizontally with respect to the electrode surface. The outcome of texturing is the creation of a relatively smooth, compact deposition morphology/microstructure (e.g., relative to a deposition in the absence of a metal conducting coating).

A metal conducting coating may comprise a plurality of aligned domains. A domain may be a particle. For example, a domain is an individual graphene sheet (e.g., graphene nanosheet or the like; graphene is referred to as a metal herein because of its metallicity in terms of electronic band structure) or a metal particle (which may be a sheet, such as, for example, a nanosheet or the like), or the like. A conducting coating may have various textures. A desired texture (of a conducting coating and/or an electrodeposited layer) may be horizontally aligned close-packed basal planes with respect to the metal member or anode surface. Such a textured surface may exhibit a desirably smooth, compact morphology/microstructure (e.g., relative to a deposition in the absence of a metal conducting coating). In various examples, a textured conducting coating comprises crystalline facets (e.g., disposed on a surface of the metal conducting coating and available for interaction, for example, with an electrolyte of an electrochemical device) and 20% to 100% (e.g., 50%-100%, 60%-100%, 70-100%, or 80%-100%), including all 0.1% values and ranges therebetween, of the crystalline facets may be desired crystalline facets. A desired crystal facet may be a close packed plane, such as, for example, a (002) plane in hexagonal close packed structures, a (111) plane in face centered cubic structures, (110) plane in body centered cubic structures, or the like. The percentage of desired crystalline facets may be determined by methods known in the art. In various examples, the percentage of desired crystalline facets may be determined by X-ray diffraction.

A metal conducting coating can comprise various metals or metal alloys. In various examples, a metal conducting coating may be the same metal(s) as or different metal/metal(s) than the metal(s) of the metal member and/or the metal conducting coating is the reduced form (i.e., metal form) of the metal-ions of the metal ion-conducting electrochemical device or different metal/metals than the reduced form (i.e., metal form) of the metal-ions of the metal ion-conducting electrochemical device.

The metal of the metal conducting coating may be a metal or metal alloy that is not the reduced form of conducting metal ions of an electrochemical device. For example, hydrothermally synthesized (111)-textured Au nano-sheets were coated on a current collector.

In various examples, the metal conducting coating exhibits one or both of the following: the metal conducting coating preferentially exposes a certain set of crystal facets, the lattice misfit between the exposed facet and the anode metal is small, i.e., less than 20% or less than 15%. Without intending to be bound by any particular theory, it is considered that when these conditions are met metal can be epitaxially electrodeposited, which may be reversible, on an anode surface (e.g., at least a portion of an exterior surface of the metal conducting coating of the anode).

In an illustrative example, the metal conducting coating is graphene and zinc is the metal produced by electrodeposition (which may be bulk metal deposition). In other illustrative examples, the metal conducting coating is Au or Ag and the metal produced by electrodeposition (which may be bulk metal deposition) is Al. In yet other illustrative examples, the metal conducting coating is Zr or Ti and the metal produced by electrodeposition (which may be bulk metal deposition) is Mg. In still other illustrative examples, the metal conducting coating is Fe, Ta, or Cr and the metal produced by electrodeposition (which may be bulk metal deposition) is Li.

In various examples, the metal conducting coating has a hexagonal close packed (hcp) crystal structure (e.g., magnesium, zinc, zirconium, titanium, and the like) and the metal produced by electrodeposition has hcp crustal structure (e.g., magnesium, zinc, and the like). In other examples, the metal conducting coating has a body-centered cubic (bcc)

crystal structure (e.g., iron, magnesium, tantalum, molybdenum, chromium, vanadium, tungsten, and the like) and the metal produced by electrodeposition has bcc crystal structure (e.g., sodium, lithium, potassium, and the like). In various other examples, the metal conducting coating has a face-centered cubic (fcc) crystal structure (e.g., metals, such as, for example, silver, gold, and the like) and the metal produced by electrodeposition has fcc crystal structure (e.g., metals, such as, for example, aluminum metal and the like).

A metal conducting coating may have the same crystal structure as the metal produced by electrodeposition. It may not be necessary that the metal conducting coating has the same crystal structure as the metal (bulk metal) produced by electrodeposition. The metal conducting coating may have a different crystal structure than the metal (bulk metal) produced by electrodeposition. The metal conducting coatings may be processed such that a desired surface (e.g., textured surface) is formed.

A metal conducting coating may be formed by electrochemical deposition, which may be electrodeposition. In various examples, the electrochemical deposition is electrodeposition of the reduced form of one or more chemically distinct types of metal ions present in an electrolyte used in a battery cell, electroplating apparatus, or electrochemical coating device. In various examples, a shear force is applied by rotating a metal member during electrochemical deposition of the metal conducting coating. In various examples, the metal conducting coating is formed by imposing a hydrodynamic flow, mechanical stress, or strain field (which can create texturing (e.g., long range order) in the metal conducting coating). The ordering may be produced using a rotating a metal member agitated by an external field or by exploiting locally-generated electroconvective fields at the ion-selective interfaces at which electrochemical deposition of the metals occur.

In various examples, a metal conducting coating, which may be an epitaxial conducting coating, is disposed on at least a portion of a surface, which may be an exterior surface, of a metal member (e.g., all portions of the metal member that would be or are in contact with the electrolyte of the metal ion-conducting electrochemical device). The metal conducting coating may promote epitaxial electrodeposition, which may be reversible, of the reduced form the metal-ions of an ion-conducting electrochemical device.

A metal conducting coating (or an anode comprising one or more conducting coating(s)) may further comprise an electrodeposited metal layer disposed on at least a portion of an exterior surface of the metal conducting coating (e.g., at least a portion or all portions of the metal member that would be or are in contact with the electrolyte of the metal ion-conducting electrochemical device). The electrodeposited layer may be the reduced form (i.e., metal form) of the metal ions of a metal ion-conducting battery. For example, epitaxial electrodeposition is provided by a conducting coating that has 20% or less lattice mismatch (e.g., 10% or less, 5% or less, 4% or less, 3% or less, 2% or less, or 1% or less), with the reduced form (i.e., metal form) of the metal-ions of the metal ion-conducting electrochemical device. When the lattice mismatch is greater than 20%, the epitaxial electrodeposition may also occur on a textured metal conducting coating, which may have exposed a particular (e.g., oriented) crystal facet or plane), in which a certain crystal facet may be exposed (e.g., a close packed plane, such as, for example, a (001) plane in hexagonal close packed structures, a (111) plane in face centered cubic structures, (110) plane in body centered cubic structures, and the like). In various examples, the interface between the metal conducting coating and electrodeposited layer is coherent or semicoherent.

An anode may also comprise a layer of electrodeposited metal disposed on at least a portion of an exterior surface of the metal conducting coating. In various examples, an anode further comprises an electrodeposited layer of a metal (which may be the reduced form the metal-ions of the ion-conducting electrochemical device) disposed on at least a portion of an exterior surface of the metal conducting coating. This electrodeposited layer may be alternatively referred to as a bulk metal layer. This electrodeposited layer may be formed during operation (e.g., plating) of the electrochemical device.

The metal conducting coating may epitaxially template deposition of the reduced form (i.e., metal form) of the metal ions of an electrochemical device (e.g., a metal ion-conducting battery, which may be a primary or secondary metal-ion conducing battery). In various examples, the metal-ions lithium ions, sodium ions, potassium ions, calcium ions, magnesium ions, zinc ions, aluminum ions, iron ions, and the like and the reduced form (e.g., metal form) of the metal ions is lithium metal, sodium-metal, potassium metal, calcium metal, magnesium metal, zinc metal, aluminum metal, iron metal, and the like, respectively. The epitaxial templating may be homoepitaxial templating or heteroepitaxial templating.

An electrodeposited metal layer can have various thickness. The thickness may depend on, for example, battery components, conducting ion/electrodeposited metal, battery capacity, etc. In various examples, an electrodeposited metal layer has a thickness of 0.5 to 100 microns. The electrodeposited layer may be uniform and/or a smooth morphology (e.g., as determined by AFM, SEM, profilometer, or the like, or a combination thereof.

Without intending to be bound by any particular theory, it is considered that the interaction between the electrodeposits and metal conducting coating can result in a relatively uniform and compact electrodeposited metal layer (e.g., relative to the same system without a metal conducting coating). The electrodeposited layer may show at some crystallographic texturing. For example, a Zn electrodeposits on (002)-textured graphene exhibits (002) crystallographic texturing.

In various examples, the metal conducting coating comprises (e.g., is) a metal or metal alloy (e.g., metal alloys comprising two or more hcp metals, two or more bcc metals, or two or more fcc metals, or the like, or a combination of such metals.). Non-limiting examples of metals include gold, silver, zirconium, titanium, iron, chromium, and the like. Non-limiting examples of metal alloys include any combinations of gold, silver, zirconium, titanium, iron, chromium, or the like. A metal or metal alloy may be chemically inert and/or electrochemically stable under the electrochemical cycling conditions.

A metal conducting coating may be ordered. A metal conducting coating may be crystalline. In various examples, a metal conducting coating is single crystalline or polycrystalline.

At least a portion or all of an exterior surface of the metal conducting coating (e.g., at least a portion or all portions of the metal conducting coating that would be or is/are in contact with the electrolyte of the metal ion-conducting electrochemical device) may have crystal facets. In various examples, at least a portion or all of an exterior surface of the metal conducting coating (e.g., at least a portion or all portions of the metal member that would be or are in contact with the electrolyte of the metal ion-conducting electrochemical device) the crystal facets are a close packed plane, such as, for example, a (001) plane in hexagonal closest packed structure, a (111) plane in face centered cubic structures, (110) plane in body centered cubic structures, or the like.

A metal conducting coating can have various thicknesses. In various examples, the thickness of the metal conducting coating is a single layer (which may be a monolayer or the like) to 100 μm (μm=micron(s) or micrometer(s)), including all integer number of layers and integer nm values and ranges thereof therebetween. A single layer may be a single graphene sheet, a monolayer of a metal or monolayer of metal particles. It may be desirable that a metal conducting coating has a thickness of less than 50 μm. In various examples, a metal conducting coating has a thickness of a single layer (which may be a monolayer or the like) to 50 μm, a single layer (which may be a monolayer or the like) to 30 μm, a single layer (which may be a monolayer or the like) to 10 μm, a single layer (which may be a monolayer or the like) to 5 μm, a single layer (which may be a monolayer or the like) to 1 μm, or a single layer (which may be a monolayer or the like) to 0.5 μm.

A metal member may comprise (or be) various materials. A metal member may comprise (or be) a solid metal or a metal foam. A metal member may be a current collector. The metal member may be an active metal member (e.g., the same metal as the electrodeposited metal) or an inactive metal member (e.g., a different metal than the electrodeposited metal). Non-limiting examples of metal members include lithium metal, sodium metal, potassium metal, calcium metal, magnesium metal, zinc metal, aluminum metal, iron metal, stainless steel, copper metal (e.g., copper foil), or the like.

The metal conducting coating may be performed ex situ. In various examples, the anode is formed prior to inclusion of the anode in an electrochemical device. The metal conducting coating may be formed in situ in an electrochemical device. In various examples, the anode is formed in an electrochemical device. The metal conducting coating may be formed at least partially or continually during the plating/stripping in an operating electrochemical device.

A metal conducting coating may have one or more desirable property(ies). In various examples, the metal conducting coating has a conductivity of 10¹ to 10⁹ S/m, including all integer S/m values and ranges therebetween, the metal conducting coating is electrochemically stable against anode reaction(s) and/or electrolyte chemistry, the metal conducing coating has a desirable lattice misfit with an/or similar crystal symmetry to an electrodeposited metal, or a combination thereof.

In an aspect, the present disclosure provides anodes. An anode comprises one or more metal conducting coating(s) of the present disclosure. A portion or all of the metal conducting coatings may be epitaxial conducting coatings. The anode may be a reversible anode. In various examples, one or more or all of metal conducting coating(s) is/are made by a method of the present disclosure. Non-limiting examples of anodes are provided herein.

In various examples, the anode(s) are part of secondary batteries or secondary cells, which may be rechargeable batteries, or primary batteries or primary cells. Non-limiting examples of secondary batteries and primary batteries include Li-ion batteries, Li metal batteries, sodium-ion batteries, sodium-metal batteries, and the like. The electrodes (e.g., cathodes or anodes), electrode materials (e.g., cathode materials or anode materials), catalysts, and catalyst materials may comprise an active material, which may be a catalytic material and/or an anode material or a cathode material. Suitable examples of active materials are known in the art. Non-limiting examples of active materials provided herein. In various examples, an electrode or electrode material does not exhibit metal orphaning. In various examples, an electrode, electrode material, catalyst, or catalyst material does not comprise a binder.

The anode may comprise a current collector other than the anode material(s) (e.g., conducting coating(s) and/or metal member(s)). In an example, an anode does not comprise a metal current collector. The metal conducting coating may be disposed on a current collector (e.g., a metal current collector). The anode may be free of other conducting materials (e.g., carbon-based conducting materials and the like).

An anode may promote epitaxial electrodeposition, which may be reversible, of the reduced form the metal-ions of an ion-conducting electrochemical device. A conducing coating may comprise (or be) the same metal as the electrodeposited metal. In this case, the electrodeposition is referred to homoepitaxial electrodeposition. A conducting coating may comprise (or be) a different material than electrodeposited metal. In this case, the electrodeposition is referred to heteroepitaxial electrodeposition. For example, epitaxial electrodeposition is provided by a conducting coating that has 20% or less lattice mismatch (e.g., 10% or less, 5% or less, 4% or less, 3% or less, 2% or less, or 1% or less), with the reduced form (i.e., metal form) of the metal-ions of the metal ion-conducting electrochemical device. When the lattice mismatch is greater than 20%, the epitaxial electrodeposition may also occur on a textured metal conducting coating, which may have exposed a particular (e.g., oriented) crystal facet or plane), in which a certain crystal facet may be exposed. (e.g., a close packed plane, such as, for example, a (001) plane in hexagonal close packed structures, a (111) plane in face centered cubic structures, (110) plane in body centered cubic structures, and the like). The anode may epitaxially (e.g., homoepitaxially or heteroepitaxially) template deposition of the reduced form (i.e., metal form) of the metal-ions of the metal ion-conducting electrochemical device.

In an aspect, the present disclosure provides devices. A device comprises one or more metal conducting coating(s) and/or one or more metal anode(s). A device may exhibit epitaxial electrodeposition (e.g., homoepitaxial electrodeposition or heteroepitaxial deposition) of the metal form of the conducting ions of the device. Non-limiting examples of devices are provided herein.

A device may be an electrochemical device. Non-limiting examples of electrochemical devices include batteries, supercapacitors, fuel cells, electrolyzers, electrolytic cells, and the like.

A device can be various batteries. Non-limiting examples of batteries include secondary/rechargeable batteries, primary batteries, and the like. A battery may be an ion conducting battery. Non-limiting examples of ion-conducting batteries include lithium-ion conducting batteries, potassium-ion conducting batteries, sodium-ion conducting batteries, magnesium-ion conducting batteries, aluminum-ion conducting batteries, iron-ion conducting batteries, and the like. A battery may be a metal battery, such as, for example, a lithium-metal battery, a sodium-metal battery, magnesium-metal battery, or the like. A device may be a solid-state battery or a liquid electrolyte battery.

In the case of a device, which may be a battery, comprising an anode material or anode of the present disclosure, the device may comprise one or more cathode(s), which may comprise one or more cathode material(s). Examples of suitable cathode materials are known in the art. In various examples, the cathode material(s) is/are one or more lithium-containing cathode material(s), one or more potassium-containing cathode material(s), one or more sodium-containing cathode material(s), one or more magnesium-containing cathode material(s), one or more aluminum-containing cathode material(s), or the like. Examples of suitable cathode materials are known in the art. Non-limiting examples of lithium-containing cathode materials include lithium nickel manganese cobalt oxides, LiCoO₂, LiNi_{1/3}Co_{1/3}Mn_{1/3}O₂, LiNi_{0.5}Co_{0.2}Mn_{0.3}O₂, lithium manganese oxides (LMOs), lithium iron phosphates (LFPs), LiMnPO₄, LiCoPO₄, and Li₂MMn₃O₈, where M is chosen from Fe, Co, and the like, and combinations thereof, and the like, and combinations thereof. Non-limiting examples of sodium-containing cathode materials include Na₂V₂O₅, P2-Na_{2/3}Fe_{1/2}Mn_{1/2}O₂, Na₃V₂(PO₄)₃, NaMn_{1/3}Co_{1/3}Ni_{1/3}PO₄, Na_{2/3}Fe_{1/2}Mn_{1/2}O₂@graphene composites, and the like, and combinations thereof. Non-limiting examples of magnesium-containing cathode materials include magnesium-containing materials (such as, for example, MgMSiO₄ (M is Fe, Mn, Co, or the like) materials and MgFePO₄F materials, and the like), FeS₂ materials, MoS₂ materials, TiS₂ materials, and the like. Any of these cathodes/cathode materials may comprise a conducting carbon aid.

The device, which may be a battery, may comprise a conversion-type cathode. Non-limiting examples of conversion-type cathode materials include air (e.g., oxygen), iodine, sulfur, sulfur composite materials, polysulfides, metal sulfides, such as, for example, MoS₂, FeS₂, TiS₂, and the like, and combinations thereof.

A device, which may be a battery, may further comprise a solid electrolyte or liquid electrolyte. It may be desirable that the electrolyte by non-flammable (e.g., a non-flammable aqueous electrolyte). Examples of suitable electrolytes are known in the art.

A device may further comprise a current collector disposed on at least a portion of the anode(s). In various examples, the current collector is a conducting metal or metal alloy.

An electrolyte, a cathode, an anode, and, optionally, the current collector may form a cell of a battery. The battery may comprise a plurality of the cells and each adjacent pair of the cells is separated by a bipolar plate. The number of cells in the battery is determined by the performance requirements (e.g., voltage output and the like) of the battery and is limited only by fabrication constraints. For example, the battery comprises 1 to 500 cells, including all integer number of cells and ranges therebetween.

A metal-ion conducting secondary/rechargeable battery may comprise one or more metal conducting coating(s). A battery may further comprise an aqueous or non-aqueous electrolyte. The metal conducting coating(s) may exhibit epitaxial relation with an electrochemically deposited metal.

In various examples, a battery is a zinc-ion conducting secondary/rechargeable battery comprising one or more zinc conducting coating(s) (e.g., one or more anode(s) of the present disclosure comprising one or more graphene conducting coating(s)) and an aqueous electrolyte.

A battery may have one or more desirable property(ies). In various examples, a battery exhibits at least 1,000, at least 2,500, at least 5,000, at least 7,500, or at least 10,000, or at least 20,000 charging/discharging cycles without failure (capacity falling below 70% of the initial value); exhibits one or more or all charging/discharging cycle(s) with a Coulombic efficiency of at least 90%, at least 95%, at least 98%, or at least 99%, or at least 99.5%, or at least 99.8%; does not exhibit detectible dendritic growth and/or accumulation of electrically disconnected fragments of the metal in the inter-electrode space; exhibits one or more or all charging/discharging cycle(s) with a Coulombic efficiency of 95% or greater for 1,000 cycles or greater, 2500 cycles or greater, 5,000 cycles or greater, 7,500 cycles or greater, or 10,000 cycles or greater and/or at rate of 40 mA/cm² or greater; or any combination thereof.

An electrochemical device may be configured i) to provide a field that results in formation of one or more metal conducing coating(s) and/or one or more anode(s) of the present disclosure and/or one or more metal conducing coating(s) and/or one or more anode(s) made by a method of the present disclosure, or ii) to carry out a method of making a metal conducting coating. The field may be provided (e.g., formed) prior to operation of the electrochemical device. The field may be provided (e.g., formed) during at least a portion of (e.g., an initial portion) of the operation of the device. The electrochemical device may be configured to produce a hydrodynamic field as described herein (e.g., to form a metal conducting layer as described herein). A hydrodynamic field may be a hydrodynamic flow field. The hydrodynamic flow field may create a convective flow in the electrolyte. For example, an electrode is rotated (e.g., using a rotating-disk electrode or the like) to generate the required hydrodynamic field (e.g., the rotation of the electrode will generate the flow field in the electrolyte).

In an aspect, the present disclosure provides methods of making metal conducting coatings and anodes. A method may be used to make a metal conducting coating or an anode of the present disclosure. An at least partially aligned metal layer produced by a method of the present disclosure may be at least a portion of an anode. Non-limiting examples of methods are provided herein.

A metal conducting coating may be formed by various methods. The methods may be in situ methods or ex situ methods. A method may be carried out ex situ (e.g., to form a metal conducting coating (or an anode comprising one or more metal conducting coating(s)) that is subsequently used to construct a battery). A method may be carried out in situ (e.g., in a completely assembled battery). In various examples, the metal conducting coating can be fabricated via a shear-flow method implemented by doctor blade. In various examples, the metal conducting coating is formed (e.g., deposited) by electrochemical deposition or the like. In various examples, the substrate (e.g., metal member) is rotated during electrodeposition of the metal conducing coating.

In various examples, a method of making a metal conducting coating (e.g., a metal conducting coating of the present disclosure) disposed on at least a portion of an exterior surface of a substrate comprises: electrodepositing a metal layer on at least a portion of an exterior surface of a substrate in the presence of a field. The electrodeposition results in a formation of a metal conducting coating (e.g., a metal conducting coating of the present disclosure) disposed on at least a portion of an exterior surface.

A field may be a hydrodynamic field. The hydrodynamic flow field may create a convective flow in the electrolyte. In various examples, a hydrodynamic field is generated by a mechanical force, an electric force, a magnetic force, or the like, or a combination thereof. A hydrodynamic field may be produced by applying a force to a preformed electrochemical device.

A hydrodynamic field may be produced by rotating a substrate. In various examples, a hydrodynamic field is produced using a rotating disk electrode or the like. The substrate may be rotated such that the rate of the electrochemical deposition exceeds the mass transfer limit of the electrodeposition. Typically, the rotation rate necessary to exceed the mass transfer limit of the electrodeposition is 1 rpm to 10,000 rpm (e.g., from 10 to 1000 rpm), including all integer rpm values and ranges therebetween. In various other examples, a hydrodynamic field is produced using a flow imposed by an external stirring device (such as, for example, a mechanical or magnetic stir bar or the like. In various other examples, a hydrodynamic field is produced by application of an orthogonal magnetic field (Lorentz force) to ions moving in an electrolyte. In various other examples, a hydrodynamic field is produced using magnetically rotated micro-/nano structures dispersed in an electrolyte. In various other examples, a hydrodynamic field is produced using programmed periodic squeezing of a battery pouch cell; or the like.

It may be desirable that the field comprises (or is/has) a component normal to the deposition substrate. Without intending to be bound by any particular theory. It is considered that the normal convective flow can enhance the transport of the metal cations from the bulk electrolyte to the electrode surface. Further, it is considered that the ion-depletion effect that induces the outward growth of metal can thereby be suppressed.

An electrodeposition electrolyte solution may comprise one or more metal salt(s). Non-limiting examples of metal salts include metal sulfate salts, halide salts, metal nitrate salts, metal trifluoromethanesulfonate salts, bis(trifluoromethanesulfonyl)imide salts, and the like, and combinations thereof. Non-limiting examples of metal cations include zinc cations, lithium cations, sodium cations, potassium cations, calcium cations, aluminum cations, magnesium cations, iron cations, gold cations, silver cations, zirconium cations, titanium cations, chromium cations, copper cations, tin cations, tantalum cations, germanium cations, and the like, and combinations thereof.

An electrodeposition may be carried out in an electrolyte solution. In various examples, the electrolyte concentration comprises one or more metal salt(s) and the concentration of the metal salt(s) is 1 mM to 5 M, including all integer mM values and ranges therebetween.

It may be desirable to carry out the electrodeposition in an inert atmosphere. For reactive metals, e.g. Li, Na, K, and the like, it may be desirable that the deposition be carried out in an inert protective gas (e.g., nitrogen, argon, or the like). For non-air-sensitive metals, e.g., Zn and the like, the electrodeposition may be performed in an ambient atmosphere.

Without intending to be bound by any particular theory, it is considered the field, which may be a hydrodynamic field, produces formation of an at least partially aligned metal layer (which may be alternatively referred to as a metal conducting coating) comprising one or more metal(s) chosen from zinc, lithium, sodium, potassium, calcium, aluminum, magnesium, iron, zirconium, titanium, gold, silver, copper, chromium, tin, tantalum, germanium, and the like, or a combination thereof.

A metal of the at least partially aligned metal layer may comprise (or have) hexagonal crystalline domains, cubic crystalline domains, tetragonal crystalline domains, orthorhombic crystalline domains, monoclinic crystalline domains, triclinic crystalline domains, or the like, or a combination thereof. Thee at least partially aligned metal layer may comprise a plurality of the metal platelets (which may be a portion of or all of the platelets in the layer). Each metal platelet may be coplanar or substantially coplanar with the remaining metal platelets of the plurality of metal platelets. By substantially coplanar it is meant that at least a portion of the plurality of platelets overlaps with one or more adjacent platelets and/or at least a portion of the plurality of platelets is out of plane (relative to a plane defined by the majority of the platelets or the layer) by up to 5 degrees or up to 1 degree. The out-of-plane metal platelets may independently be out of plane by different amounts and/or orientations. They layer may conform to the shape of a surface of the substrate. In various examples, a metal platelet may have a size of 10 nm to 100 μm, including all integer nm values and ranges therebetween.

Without intending to be bound by any particular theory, it is considered the electrodeposited metal shows a preference for exposing the crystal planes that have high packing density, e.g., the close-pack plane. The “texturing” describes a process in which the electrodeposits tend to align their close-packed basal plane horizontally with respect to the electrode surface. The outcome of texturing may be the creation of a relatively smooth, compact deposition morphology/microstructure.

A metal conducting coating may comprise aligned particles. The aligned metal particles may be of a different metal than the active metal ions of an electrochemical device and the metal layer plated during operation of the electrochemical device exhibits a lattice mismatch with the at least partially aligned metal particles of 50% or less (e.g., 20% of less). The aligned metal particles may be the same metal as active metal ions of an electrochemical device and the metal layer plated during operation of the electrochemical device is homoepitaxially plated during operation of the electrochemical device. The aligned metal particles of the metal conducting coating may be a homoepitaxial substrate that results in formation of a metal layer plated during operation of the electrochemical device with surface normal of the deposited layer lying dominantly normal to the deposition substrate.

An at least partially aligned metal layer can have various thicknesses. In various examples, the at least partially aligned metal layer has a thickness (e.g., a dimension normal to the longest dimension of the at least partially aligned metal layer) of 10 μm to 1 cm (cm=centimeter(s)), including all integer micron values and ranges therebetween.

Various substrates cam be used. A substrate may comprise (or be formed from) various metals and metal alloys. Non-limiting examples of metals and metal alloys include lithium, sodium, potassium, calcium, magnesium, zinc, aluminum, iron, gold, silver, zirconium, titanium, copper, chromium, tin, tantalum, germanium, or the like, or a combination thereof). The substrate may be a sacrificial substrate. The metal conducting layer may be removed from a substrate (e.g., a sacrificial substrate) and used as a component of an anode.

A method can provide desirable results. In various examples, the method (e.g., the electrodeposition) results in one or more of the following:
the electrodeposited metal layer is brighter and/or smoother in comparison to the metal electrodeposited on a substrate without the metal conducting coating.
the electrodeposited metal layer is more compact. The porosity is lower, relative to the metal electrodeposited on a substrate without the metal conducting coating.
the plating/stripping efficiency of the metal of electrochemical device is improved relative to an electrochemical device without one or more metal conducting coating. In various examples, an electrochemical device comprising one more metal conducting coating(s) is at least 95%, at least 99%, or 99% to 100%.
a battery comprising one or more anode(s) of the present disclosure may have higher capacity retention and/or longer cycle life relative to a battery without one or more anode(s).

In an aspect, the present disclosure provides methods of operating an electrochemical device. The methods provide an electrochemically deposited layer of a metal formed by the reduction of the metal-ions of the metal-ion conducting electrochemical device.

In various examples, during an epitaxial electrodeposition process at an anode of the present disclosure, which may be present in an electrochemical devices, such as, for example, a battery, an electrochemically inactive substrate with the right (or appropriate) crystal symmetry and lattice parameters would, upon charging, facilitate the homoepitaxial or heteroepitaxial nucleation and growth of the electrochemically active metal in a strain-free or substantially strain-free state. Once the active metal nucleates cover the surface of the substrate, the as-deposited metal layer would then serve as the new substrate that facilitates subsequent self-templated, homoepitaxial deposition to create large and uniform metal coatings at the electrode. Upon discharging, the metal is stripped away while the electrochemically inactive substrate remains intact and therefore available for a subsequent cycle of charge and discharge.

In an example, an electrochemical device is under current flow and an electrochemically deposited layer of a metal formed by the reduction of the metal-ions of the metal-ion conducting electrochemical device is formed on at least a portion of the metal conducting coating of the electrochemical device. The electrochemically deposited layer may be reversibly formed. In various examples, the electrochemically deposited layer is reversibly formed (e.g., under charging/discharging conditions), at least 1,000, at least 2,500, at least 5,000, at least 7,500, or at least 10,000 times without failure and the electrochemical deposition may exhibit a Coulombic efficiency of at least 90%, at least 95%, at least 98%, least 99%, or at least 99.5%. The interface between the metal conducting coating and electrodeposited layer may be coherent or semicoherent. In the case where the electrodeposited layer is formed multiple times, at least a portion or all of the interfaces between the metal conducting coating and electrodepostited layer may, independently, be coherent or semicoherent.

The steps of the methods described in the various embodiments and examples disclosed herein are sufficient to produce a metal conducting coating, an anode, or device, or carry out a method of the present disclosure. Thus, in various embodiments, a method consists essentially of a combination of the steps of the methods disclosed herein. In various other embodiments, a method consists of such steps.

In various examples, the following Statements describe anodes, devices, methods, and electrochemical devices of the present disclosure:
Statement 1. An anode, which may be for a metal ion-conducting electrochemical device, comprising (consisting essentially of or consisting of) a metal member; and a metal conducting coating, which may be an epitaxial (e.g., a homoepitaxial) metal conducing coating, disposed on at least a portion of the metal member (e.g., all portions of the metal member that would be or are in contact with the electrolyte of the metal ion-conducting electrochemical device).
Statement 2. An anode according to Statement 1, where the metal conducting coating epitaxially (e.g., homoepitaxially) templates deposition of the reduced form (i.e., metal form) of the metal-ions of the metal ion-conducting electrochemical device.
Statement 3. An anode according to Statement 1 or 2, where the metal conducting coating is a metal (e.g., lithium, sodium, potassium, calcium, magnesium, zinc, aluminum, iron, or the like.
Statement 4. An anode according to any one of the preceding Statements, where the metal conducting coating is a metal (e.g., gold, silver, zirconium, titanium, iron, copper, chromium, or the like) or a metal alloy (e.g., a metal alloy of any combination of gold, silver, zirconium, titanium, iron, copper, chromium, or the like).
Statement 5. An anode according to any one of the preceding Statements, where the metal conducting coating is crystalline.
Statement 6. An anode according to any one of the preceding Statements, where at least a portion or all of an exterior surface of the metal conducting coating (e.g., at least a portion or all portions of the metal conducting coating that would be or are in contact with the electrolyte of the metal ion-conducting electrochemical device) have crystal facets (e.g., a close packed plane, such as, for example, a (001) plane in hexagonal closest packed structure, a (111) plane in face centered cubic structures, (110) plane in body centered cubic structures, and the like).
Statement 7. An anode according to any one of the preceding Statements, where the thickness of the metal conducting coating is in the form of a monolayer layer or multilayers and/or a thickness of a monolayer up to and including 500 μm (e.g., up to and including 100 nm), including all integer number of layers and integer nm values and ranges thereof therebetween.
Statement 8. An anode according to any one of the preceding Statements, where the metal conducting coating has a conductivity of 101 to 10⁹ S/m, including all integer S/m values and ranges therebetween.
Statement 9. An anode according to any one of the preceding Statements, where the metal conducting coating is deposited by electrochemical deposition and the metal conducting coating is subjected to a field during deposition.
Statement 10. An anode according to Statement 9, where the field is a shear force, compressive force, electrical field, magnetic field, or the like.
Statement 11. An anode according to any one of the preceding Statements, where the metal-ions of the metal ion-conducting electrochemical device are lithium ions, sodium ions, potassium ions, calcium ions, magnesium ions, zinc ions, aluminum ions, iron ions, or the like.
Statement 12. An anode according to any one of the preceding Statements, where the metal member (which may be an active metal member (e.g., the same metal as the electrodeposited metal) or an inactive metal member (e.g., a different metal than the electrodeposited metal)) is lithium metal, sodium metal, potassium metal, calcium metal, magnesium metal, zinc metal, aluminum metal, iron metal, stainless steel, copper metal (e.g., copper foil), or the like.
Statement 13. A device comprising one or more anode of the present disclosure (e.g., one or more anode of any one of Statements 1-12 and/or one or more anode made by a method of the present disclosure).
Statement 14. A device according to Statement 13, where the device is an electrochemical device. The conduction process of the electrochemical device may involve reduction of metal ions to form a metal and oxidation of that metal to form metal ions.
Statement 15. A device according to Statement 14, where the electrochemical device is a battery (e.g., a secondary/rechargeable battery), a supercapacitor, a fuel cell, an electrolyzer, an electrolytic cell, or the like.
Statement 16. A device according to Statement 15, where the battery is an ion-conducting battery.
Statement 17. A device according to Statement 16, where the ion-conducting battery is a lithium-ion conducting battery, a potassium-ion conducting battery, a sodium-ion conducting battery, a calcium-ion conducting battery, a magnesium-ion conducting battery, a zinc-ion conducting battery, an aluminum-ion conducting battery, iron-ion conducting battery, or the like.
Statement 18. A device according to any one of Statements 15-17, where the battery further comprises a cathode (e.g., a cathode comprising a conversion material or intercalation material) and/or one or more electrolyte and/or, optionally, one or more current collector and/or, optionally, one or more additional structural components. Examples of conversion materials and intercalation materials are known in the art.
Statement 19. A device according to Statement 18, where the electrolyte is a liquid electrolyte or solid-state electrolyte.
Statement 20. A device according to Statement 19, where the liquid electrolyte is an aqueous electrolyte or a non-aqueous electrolyte (e.g., carbonate-based electrolytes, ether-based electrolytes, or the like, or combinations thereof).
Statement 21. A device according to any one of Statements 18-20, where the one or more additional structural component is chosen from bipolar plates, external packaging, and electrical contacts/leads to connect wires, and combinations thereof.
Statement 22. A device according to any one of Statements 15-21, where the battery comprises a plurality of cells, each cell comprising one or more electrode (e.g., one or more cathode and/or anode) or one or more electrode material (e.g., one or more cathode material and/or anode material), and optionally, one or more anode(s), electrolyte(s), current collector(s), or a combination thereof.
Statement 23. A device according to Statement 22, where the battery comprises 1 to 500 cells.
Statement 24. A device according to any one of Statement 14-23, where device is configured so that the conducting metal ions electrodeposit (e.g., reversibly electrodeposit) on at least a portion or all of the surface of the conducting coating in contact with the electrolyte forming a metal layer comprising one or more crystalline domains or a crystalline metal layer.
Statement 25. A device according to Statement 24, where the electrochemically deposited metal layer has low surface area and/or high density. The density of the epitaxially deposited metal may be bulk metal density or substantially bulk metal density (e.g., within 5% or less, 4% or less, 3% or less, 2% or less, 1% or less, or 0.1% or less of bulk density.
Statement 26. A device according to Statement 24 or 25, where the electrochemically deposited metal layer comprises metal layers, which may be uniform.
Statement 27. A device according to any one of Statements 15-26, where battery exhibits one or more of the following: the battery does not exhibit detectible (e.g., detectible by imaging techniques, such as, for example, SEM, TEM, and the like) dendritic growth (e.g., dendritic growth pattern) and/or orphaning, a plating and/or stripping Coulombic efficiency of 95% or greater, 98% or greater, 99% or greater, or 99.5% or greater, a plating and/or stripping Coulombic efficiency of 95% or greater, 98% or greater, 99% or greater, or 99.5% or greater for 10,000 cycles or greater and/or at rate of 40 mA/cm² or greater.
Statement 28. A method of making a metal conducting coating (e.g., a metal conducting coating of the present disclosure) disposed on at least a portion of an exterior surface of a substrate comprising: electrodepositing a metal layer on at least a portion of an exterior surface of a substrate in the presence of a field, where a metal conducting coating (e.g., a metal conducting coating of the present disclosure) disposed on at least a portion of an exterior surface of a substrate is formed. The metal conducting coating may be a metal conducting coating of an anode of the present disclosure (e.g., an anode of any one of Statements 1-12).
Statement 29. A method of making a metal conducting coating according to Statement 28, where the field is a hydrodynamic flow field.
Statement 30. A method of making a metal conducting coating according to Statement 28 or 29, where the hydrodynamic field is generated by a mechanical force, an electric force, a magnetic force, or the like, or a combination thereof.
Statement 31. A method of making a metal conducting coating of any one of Statements 28-32, where the hydrodynamic field is produced by rotating the substrate (e.g., using a rotating disk electrode or the like; flow imposed by an external stirring device (e.g., a mechanical or magnetic stir bar or the like); application of an orthogonal magnetic field (Lorentz force) to ions moving in an electrolyte; magnetically rotated micro-/nano structures dispersed in an electrolyte; programmed periodic squeezing of a battery pouch cell; or the like).
Statement 32. A method of making a metal conducting coating of any one of Statements 28-30, where the substrate is rotating such that the rate of the electrochemical deposition exceeds the mass transfer limit of the electrodeposition.
Statement 33. A method of making a metal conducting coating of any one of Statements 28-31, where the field is/has a component normal to the deposition substrate.
Statement 34. A method of making a metal conducting coating of any one of Statements 28-33, where the electrodeposition electrolyte solution comprises one or more metal salt(s).
Statement 35. A method of making a metal conducting coating of any one of Statements 28-34, where the electrodeposition is carried out in an electrolyte solution.
Statement 36. A method of making a metal conducting coating of any one of Statements 28-35, where the electrodeposition is carried out in an inert atmosphere.
Statement 37. A method of making a metal conducting coating of any one of Statements 28-36, where the hydrodynamic field causes the formation of an at least partially aligned metal layer (which may be alternatively referred to as a metal conducting coating) comprising one or more metal(s) chosen from zinc, lithium, sodium, potassium, calcium, aluminum, magnesium, iron, zirconium, titanium, gold, silver, copper, chromium, tin, tantalum, germanium, and the like, or a combination thereof.
Statement 38. A method of making a metal conducting coating of any one of Statements 28-37, where the metal of the at least partially aligned metal layer has hexagonal crystalline domains, cubic crystalline domains, tetragonal crystalline domains, orthorhombic crystalline domains, monoclinic crystalline domains, triclinic crystalline domains, or the like, or a combination thereof.
Statement 39. A method of making a metal conducting coating of any one of Statements 28-38, where the at least partially aligned metal layer comprises a plurality of the metal platelets (which may be a portion of or all of platelets in the layer).
Statement 40. A method of making a metal conducting coating of any one of Statements 28-39, where the at least partially aligned metal layer has a thickness (e.g., a dimension normal to the longest dimension of the at least partially aligned metal layer) of 10 μm to 1 cm, including all integer micron values and ranges therebetween.
Statement 41. A method of making a metal conducting coating of any one of Statements 28-40, where the substrate is chosen from metals and metal alloys.
Statement 42. A method of making a metal conducting coating of any one of Statements 28-41, where the electrodeposition results in one or more of the following:
   the electrodeposited metal layer is brighter and/or smoother in comparison to the metal electrodeposited on a substrate without the conducting coating.
   the electrodeposited metal layer is more compact. The porosity is lower, relative to the metal electrodeposited on a substrate without the conducting coating.
   the plating/stripping efficiency of the metal of electrochemical device is improved relative to an electrochemical device without one or more metal conducting coating. In various examples, an electrochemical device comprising one more metal conducting coating(s) is at least 95%, at least 99%, or 99% to 100%.
   a battery comprising one or more anode(s) of the present disclosure may have higher capacity retention and/or longer cycle life relative to a battery without one or more anode(s).
Statement 43. A method of making a metal conducting coating of any one of Statements 28-42, where the at least partially aligned metal layer is at least a portion of an anode (e.g., an anode of the present disclosure, such as, for example, an anode of any one of Statements 1-12).
Statement 44. A method of making a metal conducting coating of any one of Statements 28-43, where the aligned metal particles of the metal conducting coating are of a different metal than the active metal ions of an electrochemical device and the metal layer plated during operation of the electrochemical device exhibits a lattice mismatch with the at least partially aligned metal particles of 50% or less (e.g., 20% of less).
Statement 45. A method of making a metal conducting coating of any one of Statements 28-44, where the aligned metal particles of the metal conducting coating are the same metal as active metal ions of an electrochemical device and the metal layer plated during operation of the electrochemical device is homoepitaxially plated during operation of the electrochemical device.
Statement 46. An electrochemical device configured i) to provide a field that results in formation of one or more metal conducing coating(s) and/or one or more anode(s) of the present disclosure (e.g., one or more metal conducing coating(s) and/or one or more anode(s) of any one of Statements 1-12) and/or ii) one or more metal conducing coating(s) and/or one or more anode(s) made by a method of the present disclosure (e.g., one or more metal conductive coating(s) of any one of Statements 28-45), or ii) to carry out a method of any one of Statements 28-45.

The following example is presented to illustrate the present disclosure. The example is not intended to be limiting in any manner.

### Example

This example describes functionalized cross-linked polymer networks of the present disclosure. The example also describes methods of making functionalized cross-linked polymer networks and uses thereof.

Spontaneous and field-induced crystallographic reorientation of metal electrodeposits at battery anodes. Morphological evolution during electrochemical deposition has reemerged as an important fundamental science question owing to the important role it plays in determining the performance of energy-dense electrochemical cells that utilize metals as anodes. The propensity of most metal anodes of contemporary interest (e.g., Li, Al, Na, Zn) to deposit in non-planar, dendritic morphologies during battery charging is considered a fundamental barrier to achievement of high anode reversibility—a requirement for progress towards next-generation battery technologies able to deliver higher capacity and lower cost storage of electrical energy. The initiation and propagation of metal dendrites from dilute liquid electrolytes has been actively studied for over one hundred years and conventionally thought to be a natural consequence of ion depletion owing to sluggish mass transport in the electrolyte.

A subset of these problems centered around electrodeposition of metals, particles, and polymers, where the solidification transition is electrochemically driven, was examined. The critical role electrodeposition has played as a scalable manufacturing process for creating well-defined, conformal coatings on conductive substrates was a motivation. It is also driven by the important role that controlled electrodeposition of metals is thought to play in achieving high levels of reversibility in rechargeable batteries that utilize metal anodes. This this interest spans cells that either deliberately use metals as the anode for achieving greater storage per unit mass/volume or in which the metal anode is formed spontaneously on a too quickly charged insertion electrode (e.g., the graphite anode used in emergent fast-charge, Lithium ion battery technology). The current contribution therefore focuses on the physico-chemical processes that drive such instabilities in metal electrodeposition under conditions relevant in batteries.

In this example, the fundamental origins of non-planar and dendritic electrodeposition of several metals (Zn, Cu, and Li) in a three-electrode electrochemical cell bounded at one end by a rotating-disc electrode (RDE) were experimentally investigated. Rotation of the electrode creates a well-defined convective flow in the electrolyte, which allows us to systematically manipulate and study the effect of mass-transport-limited ion migration in dilute and, battery-relevant, concentrated electrolytes on electrodeposit morphology. It was found that the classical picture of ion depletion-induced nucleation and growth of metal dendrites is valid in dilute electrolytes but is essentially never relevant in the concentrated (≥1M) electrolytes typically used in rechargeable batteries. Using Zn as an illustrative example, it was found that ion depletion at the mass transport limit may be overcome by spontaneous reorientation of the plate-like Zn crystallites from orientations parallel to the electrode surface to ultimately achieve homeotropic orientations that appear to facilitate contact with electrolyte outside the depletion zone. This mechanism causes obvious transitions in texturing of the metal electrodeposition and increases the porosity of the metal electrodeposits but is highly effective in arresting growth of non-planar dendritic deposits and results in higher electrochemical reversibility than observed in dilute liquid electrolytes. Further, even modest levels of normal flow created by rotating the electrode can completely eliminate homeotropic alignment of Zn platelets to produce compact Zn electrodeposits in which the platelets are aligned parallel to the electrode and which exhibit very high (>99.6%) electrochemical reversibility. By extending the study to other metals (Cu and Li) that do not deposit as anisotropic plates, it was shown that the chemo-taxis-like process that spontaneously reorients Zn plates is quite generic for metal electrodeposition in concentrated liquid electrolytes and produces porous structures composed of open assemblies of primary electrodeposit particles. These observations can be rationalized in terms of the length scales involved in the electrodeposition process and conclude that enhanced ion transport either by spontaneous reorientation or normal flow-assisted assembly are effective in suppressing dendritic electrodeposition of metals in concentrated electrolytes.

The electrodeposition of metals in dilute (e.g., 0.05 M) and moderately concentrated (e.g., 2.5 M) electrolytes is described and it was found that transport plays fundamentally different roles. Specifically, it was found that metals do not form classical dendritic electrodeposits under electrolyte conditions typically used in electrochemical cells. Instead it was observed that the transition from planar to non-planar electrodeposition morphologies in metals is associated with the formation of highly porous, mossy structures driven by a chemotaxis-like anisotropic growth of the metal electrodeposits structures. The resultant morphologies are analogous to those attributed in the literature to metal electrodeposition regulated by a heterogeneous solid-electrolyte interphase layer. Additionally, that even moderate amounts of normal flow generated by rotating the electrode is sufficient to eliminate formation of non-planar electrodeposition at metallic electrodes and to produce highly reversible electrodeposit growth, under aggressive deposition conditions is described.

Electrochemically driven solidification reactions of metals involve two dominant steps—transport of the metal ions to an electrode, which serves as a source of electrons; and reduction of the metal ions at the electrode to produce the metal. The interplay between physical and chemical kinetics associated with the two steps has been investigated for more than one hundred years in the context of metal plating. It is known that the relative rate of transport of the metal ions to the rate at which they are reduced at the interface determine the size, morphology, and potentially even the shape of metal electrodeposits. In dilute electrolytes, the rate of ion transport in the electrolyte can be quantified using the Nernst-Planck (N-P) equation in terms of the cation flux density,

$${N}_{+} = - {D}_{+} \frac{\partial {C}_{+}}{\partial x} - \frac{{z}_{+} F}{R T} {D}_{+} {C}_{+} ∇ Φ + {C}_{+} v .$$

The rate of the surface reduction reaction may likewise be quantified by the exchange current density, iₒ. Here C₊ is the cation concentration in the electrolyte, D₊ is the diffusivity, z₊ is the valence number of the cationic species, ∇ϕ is the potential gradient, and v is the flow velocity.

In the kinetic-rate-limited regime, the rate of ion transport in the electrolyte is fast enough to provide ions to replenish the ones depleted by the surface reaction; the rate at which the solid electrodeposit forms and grows on the electrode then depends only on the rate at which electrons can be transported to reduce arriving ions. In closed electrochemical systems, such as batteries, convection is normally assumed to be unimportant and the surface reaction kinetics are much faster than the rate of ion transport to the electrode; the electrodeposition rate is therefore said to be transport-limited. At a certain deposition current, i_{L}, the rate of ion depletion at the electrode surface becomes larger than the rate of transport of fresh ions to the electrode, leading to the formation of a highly insulating ion-depletion (extendedspace charge) zone at the electrode surface. Classical transport theory predicts that in a dilute electrolyte the thickness of this depletion layer,

$${δ}_{ESCL} = 1.31 L \times {( \frac{VF}{R T} \times \frac{{λ}_{D}}{L} )}^{\frac{2}{3}} ,$$

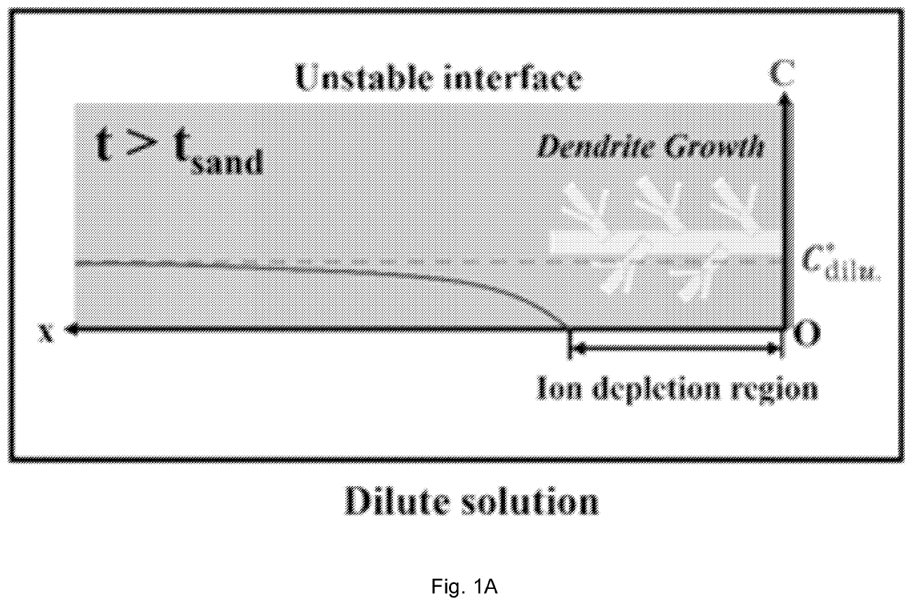

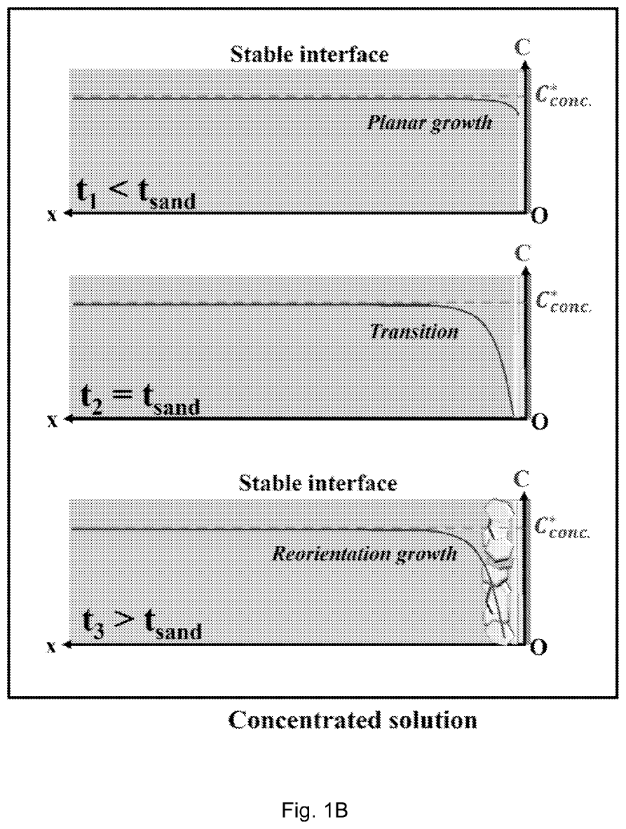

increases with the applied voltage V and decreases with the electrolyte salt concentration, through the reciprocal relationship between the Debye screening length, λ_{D}, and the square root of the salt concentration. This means that beyond a critical voltage V_{cr}≈8 RT/F, the current density ceases to depend on V, and a plot of i versus V displays a plateau at i=i_{L}. For V>>V_{cr}, both experiments and theory show that the electric field exerts a body force on charged fluid in the ESCL, which drives unstable convective fluid motions via an instability termed electroconvection. The resultant electroconvection flux augments the diffusion and migration terms in the N-P equation, leading to a new regime, termed over-limiting conductance, in the i-V curve. Metal deposition is destabilized by electroconvection because the instability produces a non-uniform flux of ions to the electrode surface. Electrochemical reduction of ions in regions of high convective flux (i.e., “hot-spots”) produces rapid growth of non-planar, fractal-like dendritic electrodeposit morphologies, as illustrated in FIG. 1A.

The large difference in electrolyte salt concentrations used in literature studies (C₀<0.1 M) of Zn, Cu, and Ag electrodeposition, which have largely validated these classical effects, in comparison to those used in battery studies (C₀≥1 M) is problematic for fundamental and practical reasons. Fundamentally, at high salt concentrations both the chemical potential gradient and the ion transport coefficients are subject to many-body, non-pairwise additive interactions, which produce complex ion-concentration dependences invalidating the simple Nernst-Planck expression for the cation flux density. Additionally, at the much smaller λ_{D} values associated with the high salt content, the ESCL may become smaller than the diffusion boundary layer thickness

$$( {δ}_{D L} = \frac{{C}_{+} \times n F \times D}{{i}_{L}} ) ,$$

meaning that ion transport through a stagnant fluid film at the electrode may dominate the interfacial dynamics of cations at the electrode. A straightforward approach for evaluating this possibility is use a rotating disc electrode (RDE) to generate a well-defined three-dimensional hydrodynamic flow field (ν=νᵣ(r, y)eᵣ+ν_{y}(y)e_{y}+ν_{θ}(r)e_{θ}), where νᵣ(r, y)=0.51ω^{3/2}v^{-1/2}ry, ν_{y}(y)=−0.51ω^{3/2}v^{-1/2}y², and ν_{θ}(r)=rω, near the electrode surface (i.e., y →0). The normal (y −) component augments the transport of ions to the electrode surface, which makes it possible to precisely manipulate the diffusion boundary layer thickness,

$${δ}_{D L , ω} = 1.61 {ω}^{- 1 / 2} {{D}^{1 / 3} ( \frac{{μ}_{s}}{ρ} )}^{1 / 6} ,$$

by varying the angular rotation rate, ω, of the electrode. Here D is the ionic diffusivity, μₛ is the viscosity of the electrolyte solvent and ρ the electrolyte mass density.

Results. To study the role of electrolyte salt concentration on electrodeposition, electrodeposition of Zn in aqueous ZnSO₄ electrolytes with three salt concentrations 0.05M, 0.5M and 2.5M was first investigated. The 2.5 M ZnSO₄ aqueous solution, as a member of the mild-pH electrolytes, is a promising next-generation Zn battery electrolyte featuring multiple favorable properties. The rationale for choosing Zn for the study is straightforward. First, Zn electrodeposition can be performed in aqueous electrolytes where complications associated with the formation of a solid electrolyte interphase (SEI) can be avoided. Zn therefore provides a platform to deconvolute the high salt concentration and SEI formation processes that are typical of electrodeposition studies for metals such as Li and Na. Zn metal is also promising in its own right as an energy-dense rechargeable battery anode and is under active research for this purpose. As acknowledged in prior literature, regulating Zn deposition morphology appears crucial because Zn can more easily cause battery short circuits owing to its Young's modulus that is one order of magnitude higher than Li (108 vs. 5 GPa).

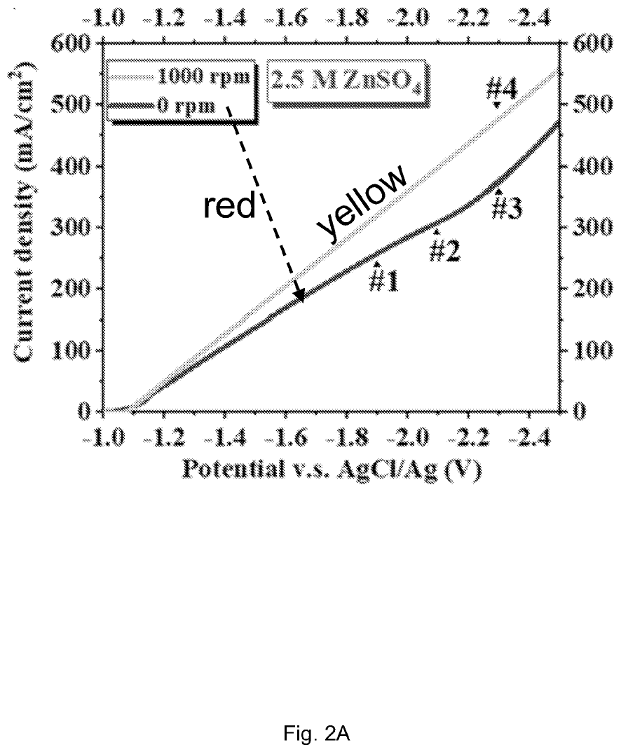

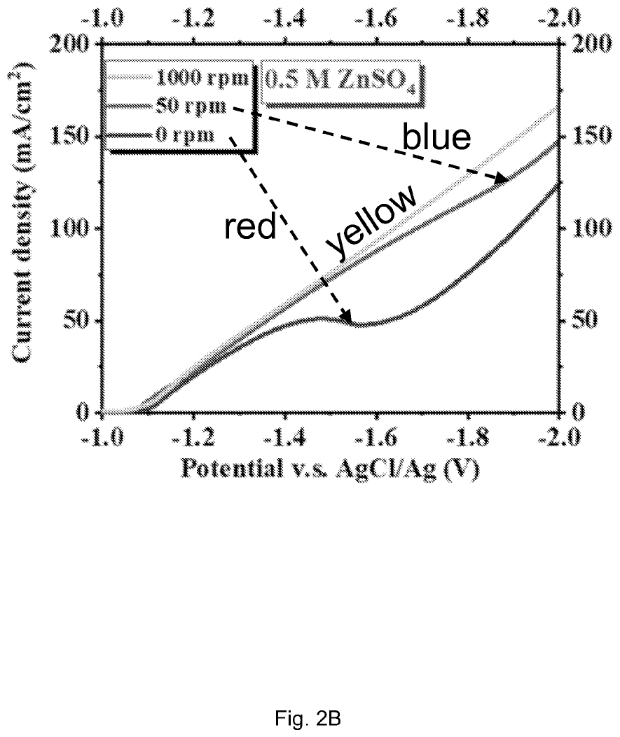

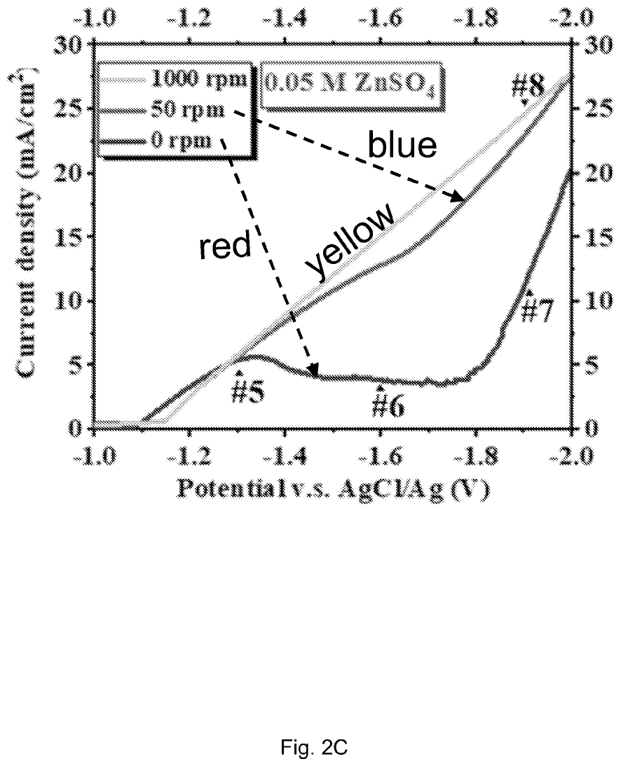

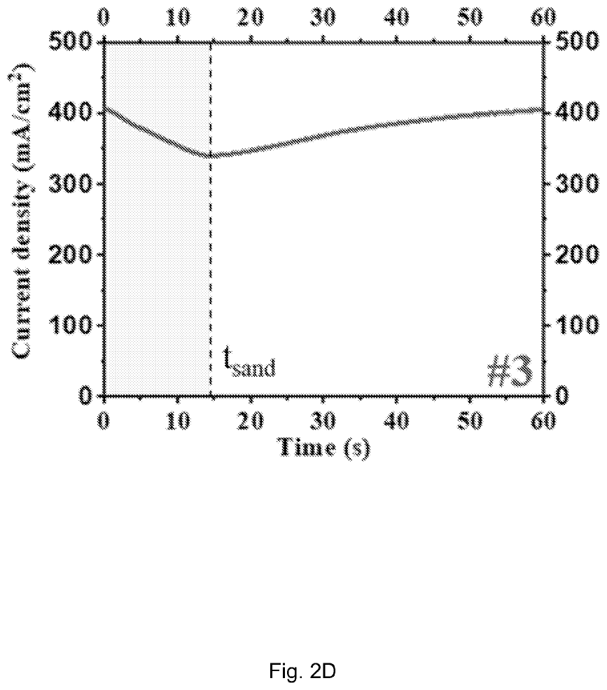

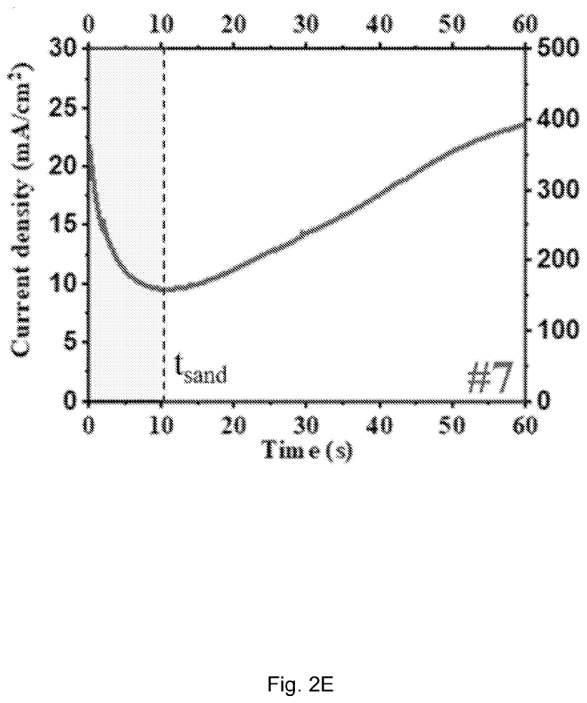

The red curves in FIGS. 2A-2C show the current-potential (i-J) curves measured using linear potential sweep voltammetry in aqueous electrolytes with low, intermediate, and high ZnSO₄ concentrations. In each of the three cases, a critical overpotential exists, above which the i-V curve deviates from the linear relation as established in the initial, below-limiting ohmic region. The ohmic behavior observed at small potentials indicates mass transport is sufficiently fast to replenish the ion consumption by the reaction so that the electrolyte conductivity remains unchanged. As the current density approaches a critical value, i.e., the limiting current, the curve slope decreases, which is indicative of the reduced conductivity caused by ion depletion. The observed limiting current densities are 300, 50 and 5 mA/cm² in 2.5, 0.5 and 0.05 M electrolytes, respectively. Our observations are consistent with the linear relationship between i_{L} and the electrolyte salt concentration. As the overpotential further increases, an over-limiting region is observable, again consistent with expectations based on the classical theory outlined in the introduction. This increase in slope is thought to reflect the initiation of additional mechanism(s) (e.g., electroconvection) that enhance the mass transport and thereby helps to overcome the diffusion limit.

The results described by the red curves should be compared with the curves in yellow and blue plotted in FIGS. 2A-2C, which show the i-V responses under similar conditions but measured with electrode rotation. With the normal flow-assisted mass transport in the RDE, the limiting and over-limiting regions of the i-V curve are noticeably absent at the higher rotation rate; instead, an ohmic region showing a linear i-V relation holds throughout the entire sweep. It confirms that the changes of the i-V curve slope observed in the cases without normal flow, including the decrease and the increase, are attributable to mass transport in the liquid electrolyte bulk. Comparing FIGS. 2A-2C, it was therefore concluded that, in both the dilute and concentrated electrolytes, mass transport governed limiting and over-limiting behaviors play an important role in ion transport in the electrolyte bulk and would therefore be expected to influence electrodeposition of Zn.

To understand the mechanisms leading to the transition from limiting to over-limiting ion transport, in concentrated and dilute ZnSO₄ (aq) electrolytes, the microstructure of Zn electrodeposits obtained from chronoamperometry, i.e., constant-potential deposition for a certain period of time, were characterized. Potentials that correspond to below-limiting, limiting, and over-limiting conditions as evidenced in the FIGS. 2A and 2C were used in the study. The time-dependent currents in the chronoamperometric deposition experiments was also monitored. For applied potential corresponding to an over-limiting region, the current density profile exhibits a negative slope before the current minimum is reached at the Sand's time (FIGS. 2D and 2E), implying the concentration of metal cations falls to zero in a fluid layer near the electrode surface. Sand's time can be calculated using the formula:

$${t}_{s α n d} = π D \frac{{( z C F )}^{2}}{4 {( i ( 1 - {t}_{+} ) )}^{2}} ,$$

where t₊is the cation transference number. The estimated Sand's times for the 2.5M and the 0.05M electrolytes are thus determined to be 11.2 and 8.5 seconds, respectively. It is further noted that both estimates are of comparable order of magnitude to the experimentally observed values. Subsequently, the current density increases after the Sand's time indicative of the initiation of additional mass transport mechanism(s). These observations from chronoamperometric electrodeposition are in good agreement with the linear sweep results discussed earlier.

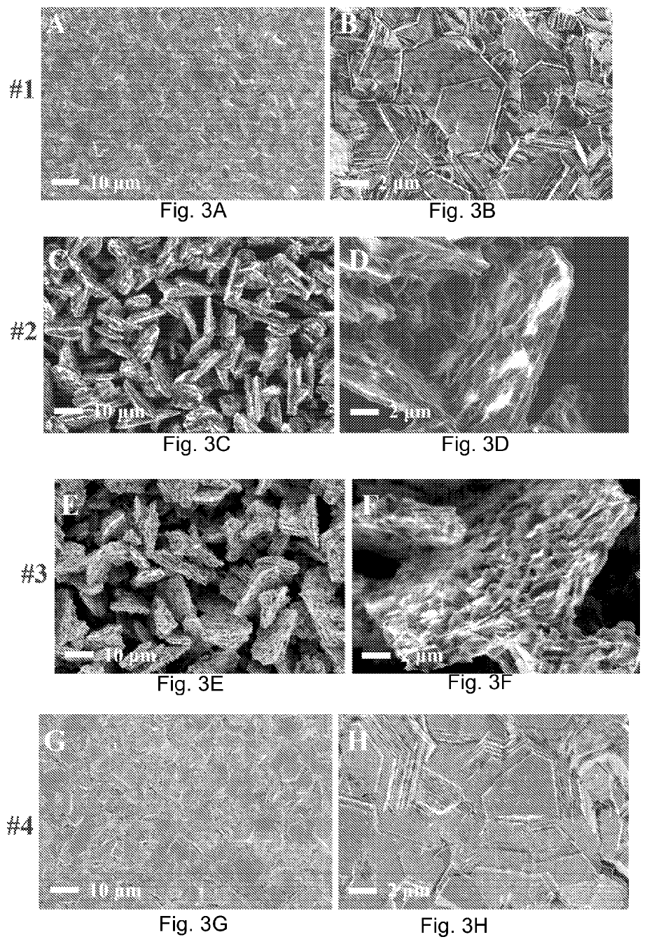

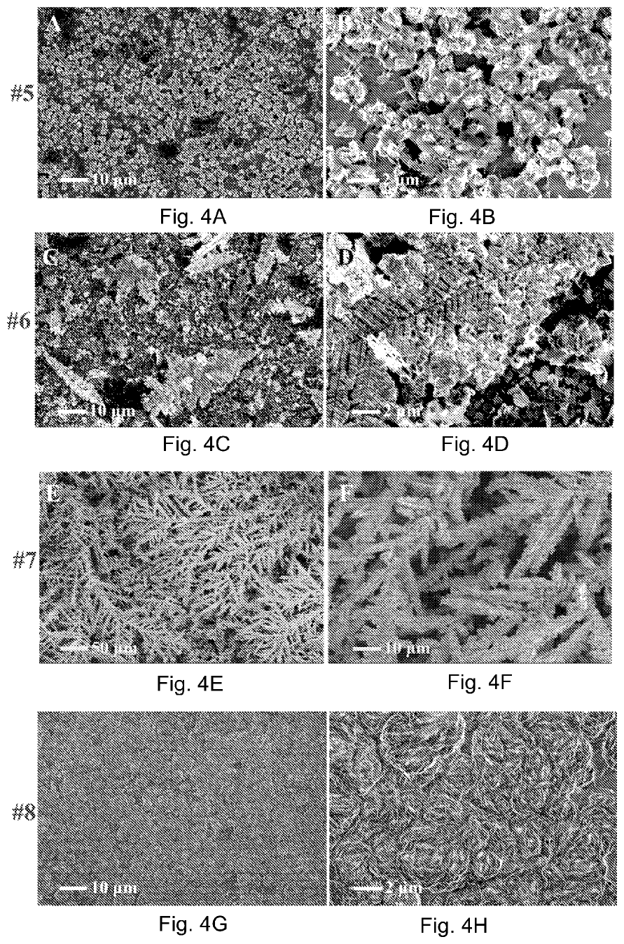

The main results are presented in FIGS. 3-4. They show the morphological evolution of Zn under different conditions revealed by scanning electron microscopy. The numbers on the left side of the images indicate the deposition potentials and rotation rate as labeled in FIG. 2A (#1-#4) and 2C (#5-#8) at which the measurements were performed. The rather clear but unexpected observation is that whereas classical, tree-like and highly branched dendrites are observed in the dilute electrolyte under mass-transfer-controlled conditions (FIGS. 4C-4F), the Zn deposited from concentrated electrolytes under such conditions exhibits a morphology that is obviously non-dendritic. Instead, the Zn deposits as vertically aligned platelets with diameter, Φ, in the range 10˜20 m. It should be noted that the areal deposition capacity used for the measurements is around 6 mAh/cm² (estimated using the current density and deposition time), which is beyond the usual areal capacity, i.e., <2 mAh/cm², employed in Zn battery studies using mild-pH electrolytes. The morphology formed in the over-limiting region can be compared with the Zn morphology formed in the below-limiting regime (FIGS. 3A-3B) or under the influence of normal flow (FIG. 3G-H) in the RDE, where the plates are observed to be clearly aligned in the plane of the electrode. The vertical alignment of Zn electrodeposits, as opposed to dendritic growth, has to our knowledge not been reported previously.

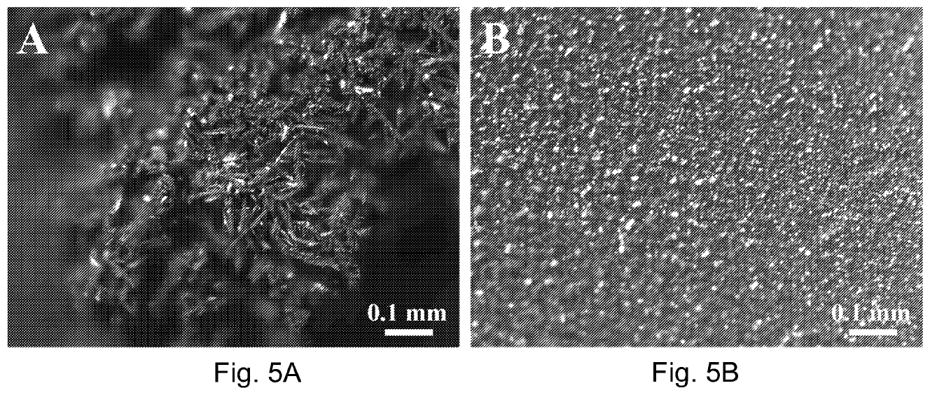

The ease with which rotation switches the plate alignment from vertical to horizontal, the correlation of the onset of Zn platelet alignment with transported-limited deposition, and the absence of classical dendritic growth in the concentrated electrolytes under transport-limited conditions lead us to hypothesize that the plate-like Zn electrodeposits may undergo a reorientation transition to maximize access to the supply of ions just outside the depletion zone. As a first test of this hypothesis, optical microscopy was performed to visualize the morphology at a larger scale (FIG. 5A-5B). The results show that the Zn morphology formed in dilute electrolyte is highly heterogeneous (FIG. 5A), featuring aggressively extending dendrites. In contrast, the Zn deposition morphology in concentrated electrolyte is homogeneous at the optical scale (FIG. 5B).

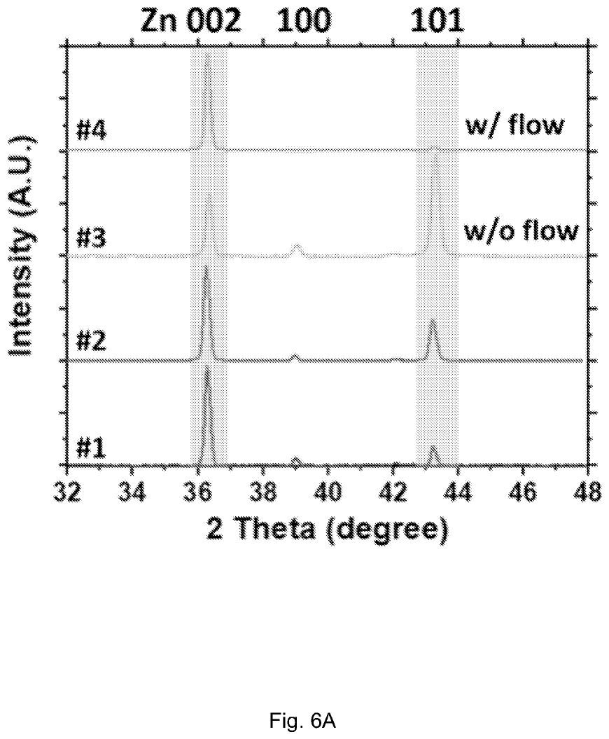

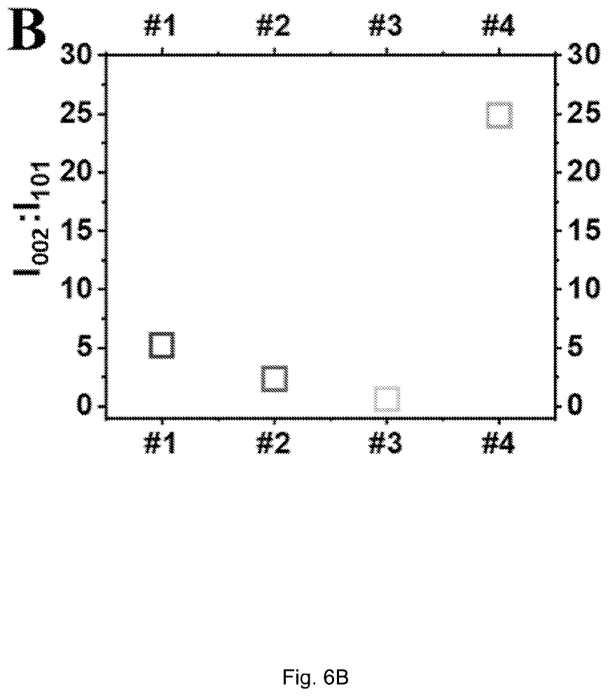

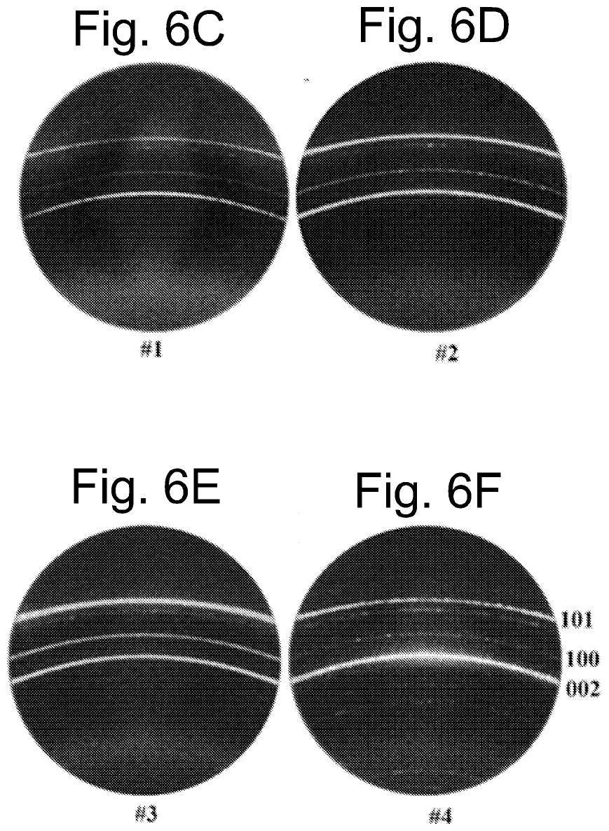

The observation that Zn tends to form plate-like deposits in concentrated electrolytes is consistent with previous post-mortem analysis of Zn battery anodes. Due to the anisotropy of the hexagonal-close-packed (HCP) zinc crystal, Zn preferentially exposes the basal plane, i.e., (002), which has the highest atomic packing density, to minimize its surface free energy. In other words, the plane normal of the plate-like Zn electrodeposits is parallel to the [002] direction of Zn crystal. Based on this connection between the microstructure and the crystal structure of Zn, the reorientation process from horizontal alignment in the below limiting regime to vertically alignment in the over-limiting regime changes the texturing behavior of the deposits, and therefore can be quantified using X-ray diffraction (XRD; see FIGS. 6A-6F). The texturing behavior is characterized by the peak intensity ratio between (002)zₙ and (101)zₙ, as can be discerned in the line scans plot (FIG. 6A) and the 2D scan plot (FIGS. 6C-6F). A greater I₀₀₂:I₁₀₁ means the deposit is more (002)-textured, i.e., more (002) planes are parallel to the substrate. As shown in FIG. 6B, the I₀₀₂:I₁₀₁ decreases from 5.2 to 0.6 as the overpotential increases. Under the influence of flow-assisted mass transport, the Zn deposits exhibits a strong (002) texturing, as indicated by the I₀₀₂:I₁₀₁ as high as 25. These XRD analyses statistically confirmed the reorientation growth induced by mass-transport limit.

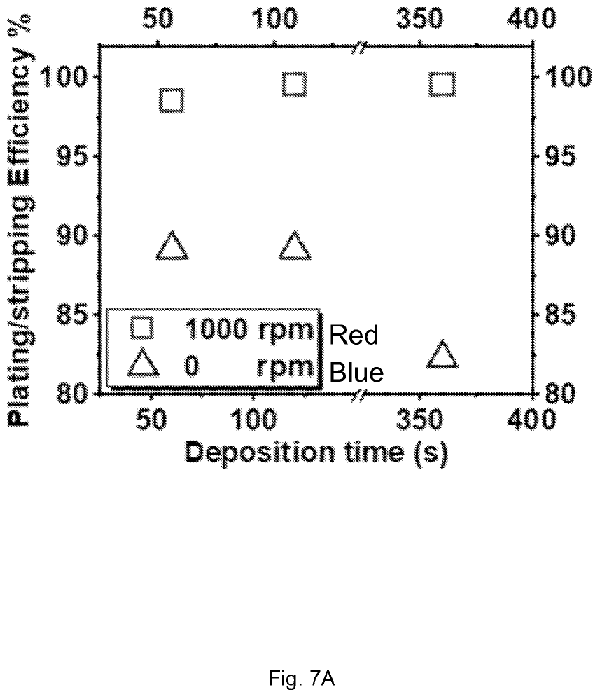

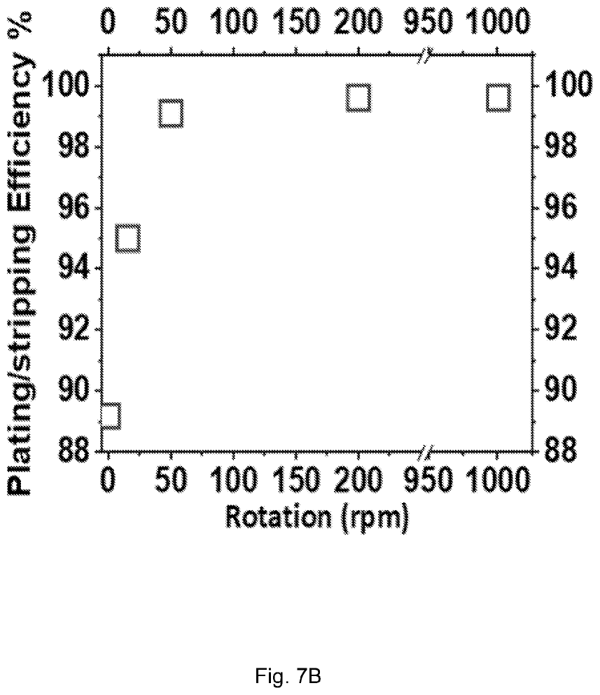

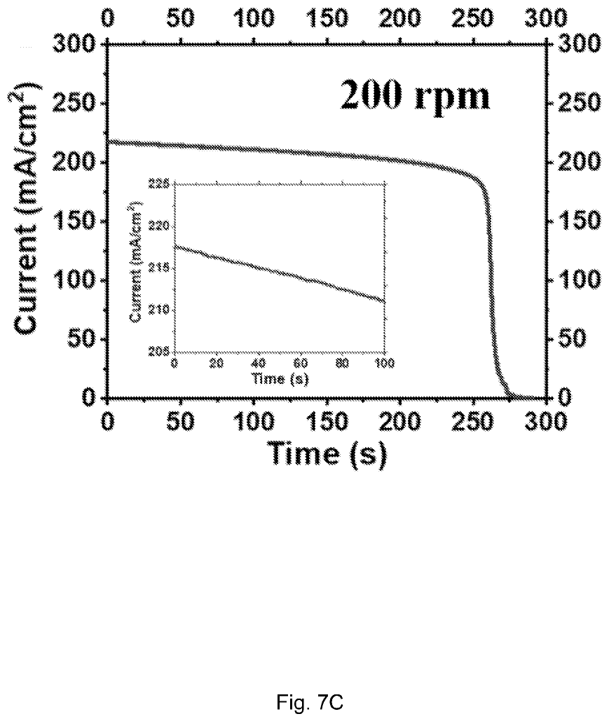

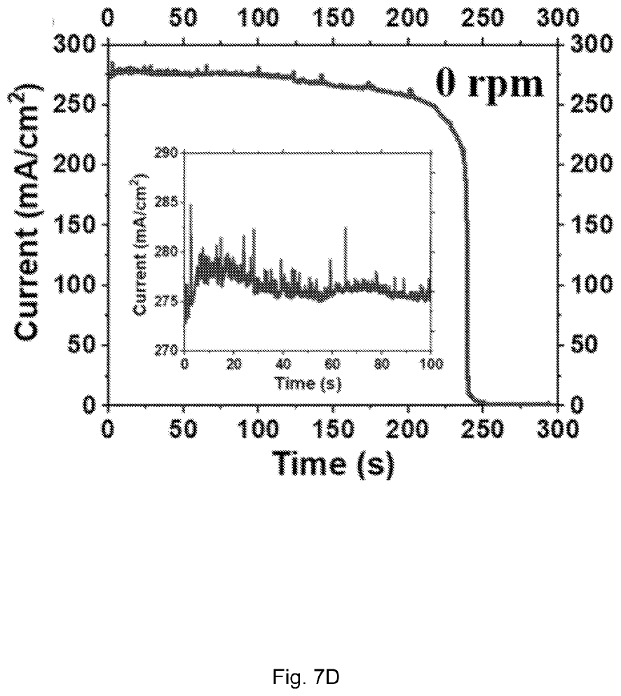

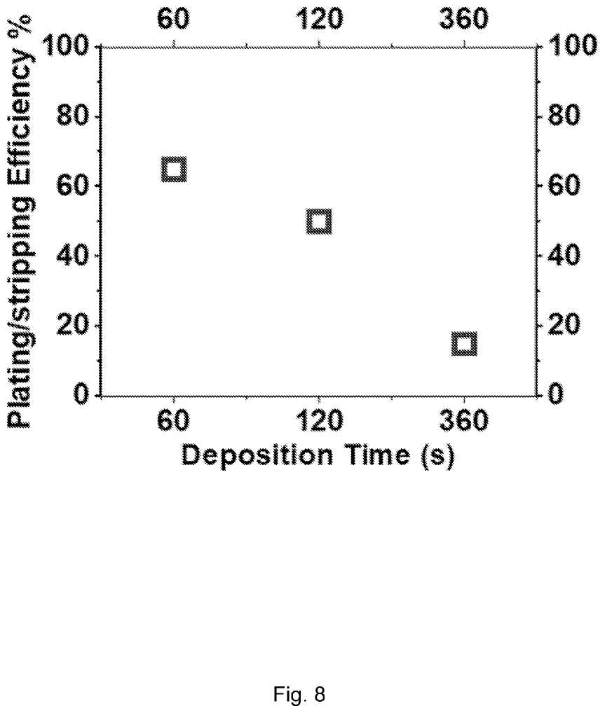

To determine the consequence of our observation on reversibility of a Zn electrode, the plating/stripping efficiency of the Zn electrodeposits was evaluated. The reoriented Zn plates formed in the over-limiting regime exhibit Coulombic efficiencies of 80 ˜90% at different areal deposition capacities (see blue points in FIG. 7A), which are similar to the reported Zn plating/stripping efficiencies in battery anodes reported in the literature. These values are significantly higher than the Coulombic efficiencies of 15%˜65% achieved by the classical dendrites formed in dilute electrolytes (FIG. 8). As shown by the red points in FIGS. 7A-7B, the compact, planar Zn deposits formed under the influence of normal flow have a close to unity (˜99.6%) reversibility! These results indicate that the electrodeposition morphologies, strongly influenced by salt concentration, flow and deposition conditions, directly determine the plating/stripping reversibility of a metal.

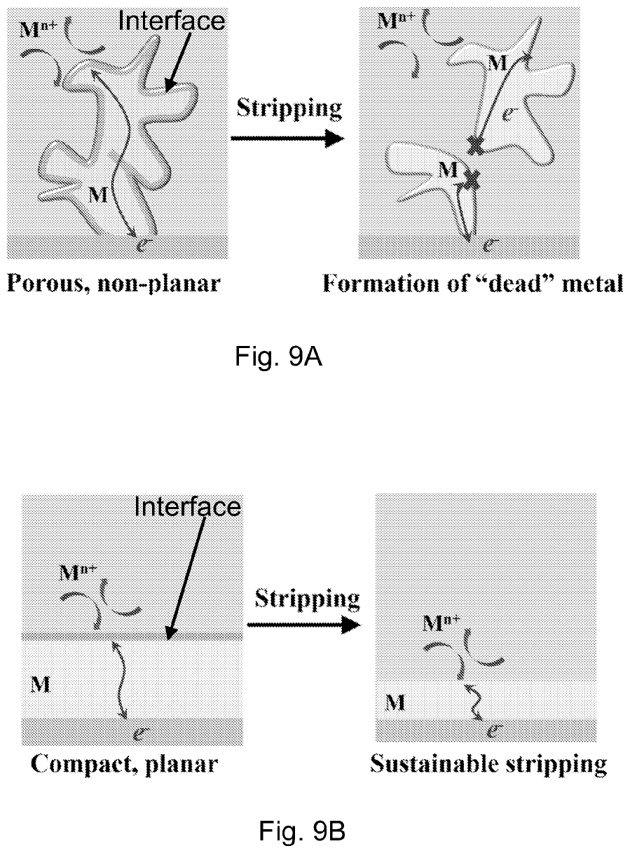

Clues to interpreting the difference in reversibility between the non-planar, reoriented Zn and the planar Zn can be discerned from FIGS. 7C-7D. As illustrated in the scheme, on a planar, compact Zn electrode, the stripping reaction evenly occurs at the interface between the metal and the liquid electrolyte (FIG. 9B); in contrast, the stripping of a porous, non-planar Zn can proceed inside the structure, leading to the mechanical disconnection/reconnection of metal deposits (forming “dead” metal) (FIG. 9A). This is evidenced in the results by the spiky current profile in the inset to FIG. 7D. These observations have obvious implications for battery anode design. Specifically, they show that although the porous Zn deposits formed by reorientation growth, as opposed to dendritic growth, are homogeneous over the electrode surface, they offer a plating/stripping efficiency that is far too low to meet the requirements of viable battery system (i.e., >99%). For stationary batteries, our results suggest that an obvious strategy to curb the reorientation growth is to introduce artificially generated normal flow to reorient the Zn plates. For portable batteries, an interphasial coating on the substrate that can epitaxially promote the planar, (002)-textured Zn growth has been suggested as an approach for crystallographic regulation of the deposition process.

Discussion. An intriguing and fundamentally important question is—what mechanism(s) leads to the distinction between the over-limiting Zn morphologies in the dilute and the concentrated electrolytes? As the length scales of the Zn electrodeposited microstructures extending from the electrode surface into the electrolyte are quite different in the two cases (e.g., Φₚₗₐₜₑ≈10˜20 μm, for reorientation growth in 2.5M electrolyte versus a primary dendrite arm length Lₐᵣₘ>200 μm for the non-planar growth in a 0.05M electrolyte), it was hypothesized that these morphologically-expressed length scales are a reflection of underlying transport length scales in the electrolyte, e.g. diffusion layer thickness δ_{DL} and/or extended space charge layer thickness δ_{ECSL}, which control electrochemical access of the growing electrodeposit structures to Zn²⁺ ions in solution.

δ_{ESCL} and δ_{DL} were calculated for the three ZnSO₄(aq) electrolyte compositions used in the study: δ_{ESCL}(2.5M) 1.6 μm, δ_{DL}(2.5M)=41 μm; δ_{ESCL}(0.5M) ≈3.5 μm, δ_{DL}(0.5M)=71 μm; and δ_{ECSL} (0.05M) ≈5.6 μm, δ_{DL}(0.05M)=256 μm. It is noticeable that δ_{DL} is consistently closer to the average size of the Zn structures observed in the SEM images (e.g., Φₚₗₐₜₑ (2.5M) is of the same order of magnitude, i.e., 10¹ μm, as δ_{DL}(2.5 M) and δ_{DL}(0.05M) and the characteristic length of primary dendrite arms are of the same order of magnitude, i.e., 10² μm. This suggests that the Zn electrodeposit growth is constrained to the diffusion layer thickness and that the Zn deposits grow to the point where mass transport limitations in the liquid electrolyte are just overcome, as illustrated in FIGS. 1A-1B. In addition to the characteristic lengths, the specific geometries of the electrodeposits can be understood based on this analysis. Plates are two dimensional structures that extend not only towards the bulk electrolyte but also sidewise; in contrast, dendrites show one dimensional characteristics by extending primarily towards the bulk electrolyte (FIGS. 1A-1B). In a dilute electrolyte, as the diffusion layer thickness is significantly greater, the electrodeposits tend to adopt a more efficient growth mode, i.e., the latter 1D dendritic pattern, to overcome the mass transport limit.

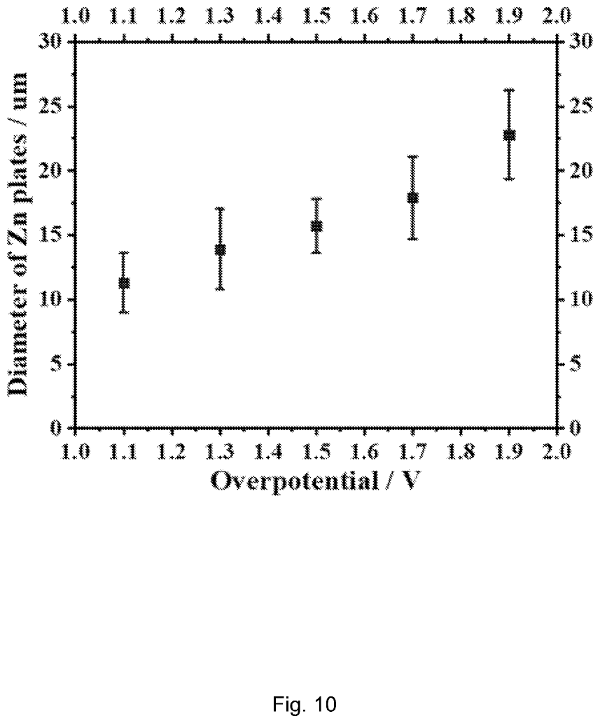

The increase in magnitude of δ_{ESCL} with increasing ion concentration nonetheless offers an-accepted, alternative explanation. Previous literature reports indicate that the slip velocity at the edge of ESCL generated by electroconvective flow may also produce a non-uniform ion flux to the electrode, driving preferential growth at dendrite tips. Related works show that the electroconvective flow can be readily attenuated by imposition of a convective cross flow. The average diameter Φ of the Zn platelets obtained after a fixed deposition time of 60 s (see FIGS. 2A-2H) was measured as a function of overpotential V, to determine whether the classical δ_{ECSL}˜V^{2/3} scaling relation holds. The results shown in FIG. 10 show that Φₚₗₐₜₑ increases more strongly than V^{2/3}, and that the relationship is nearly linear. The Nernst-Planck equation predicts a linear relation between the cation flux N+ and the overpotential. For a fixed deposition time and surface area, this would lead to the trivial result Φₚₗₐₜₑ∝V, as a larger electrodeposition amount is accumulated in the sheets over a fixed deposition time. Thus, it was concluded that δ_{DL} is the dominant length-scale that determines the size of the Zn plates.

How variations in the diffusion layer thickness influence the average size of the deposits was next studied. It is known that a convective flow produced by rotating the electrode in its plane at an angular speed ω, produces a diffusion layer thickness

$${δ}_{D L} = 1.61 {D}^{\frac{1}{3}} {ω}^{- \frac{1}{2}} {υ}^{\frac{1}{6}} ,$$

that can be systematically altered through control of ω. Here, ν is taken as the kinematic viscosity of the electrolyte solvent and δ_{DL} under the influence of normal flow in the RDE was estimated as: δ_{DL}(2.5M, 1000 rpm)=10.5 μm; δ_{DL}(0.05M, 1000 rpm)=13.3 μm. In both cases the estimated δ_{DL} is smaller than the length scale of the microstructure observed in the over-limiting region without flow, implying that both the reorientation growth observed in a concentrated electrolyte and the dendritic growth in a dilute electrolyte can be suppressed in the 1000 rpm case, which is precisely what was observed.

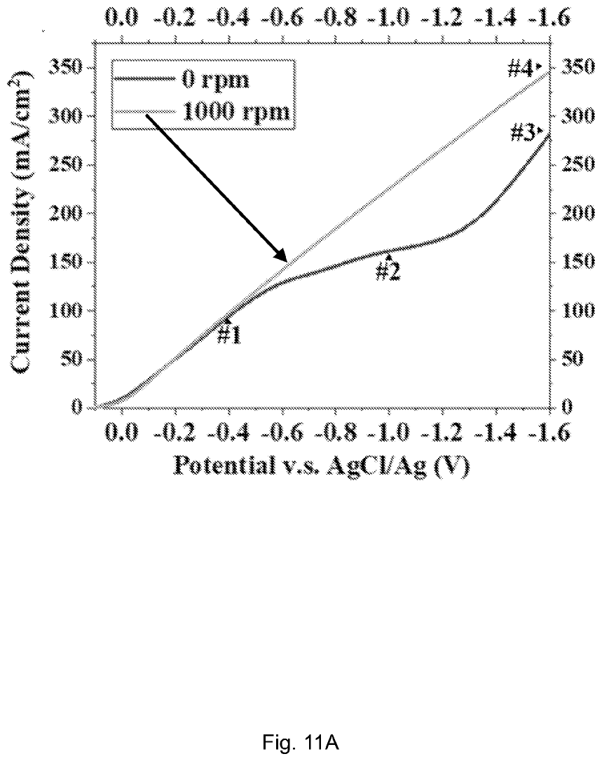

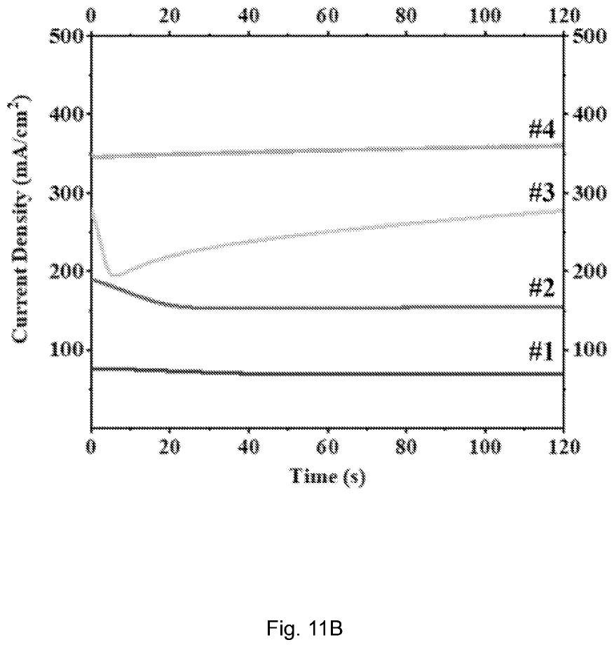

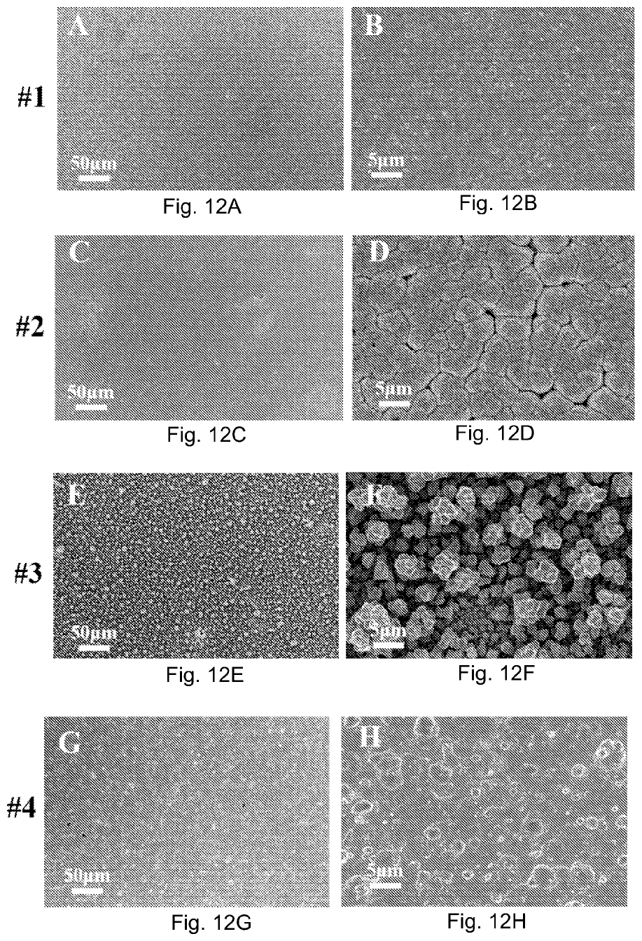

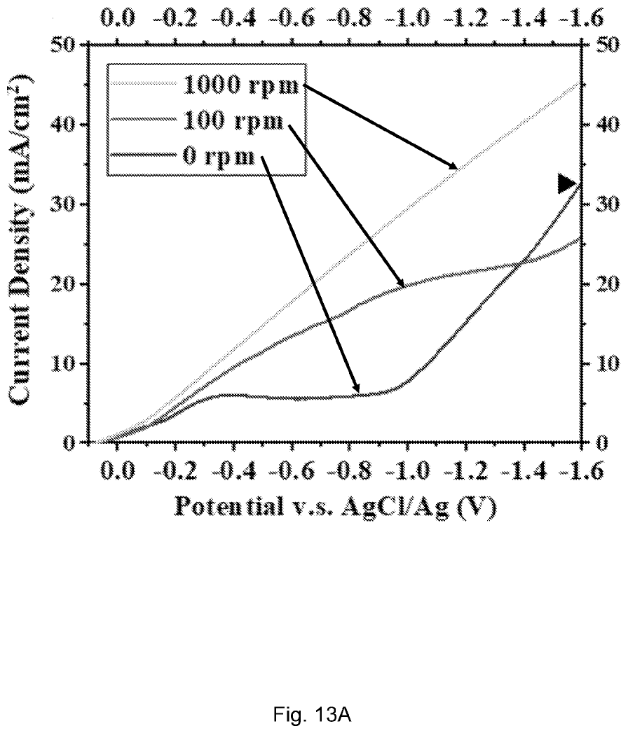

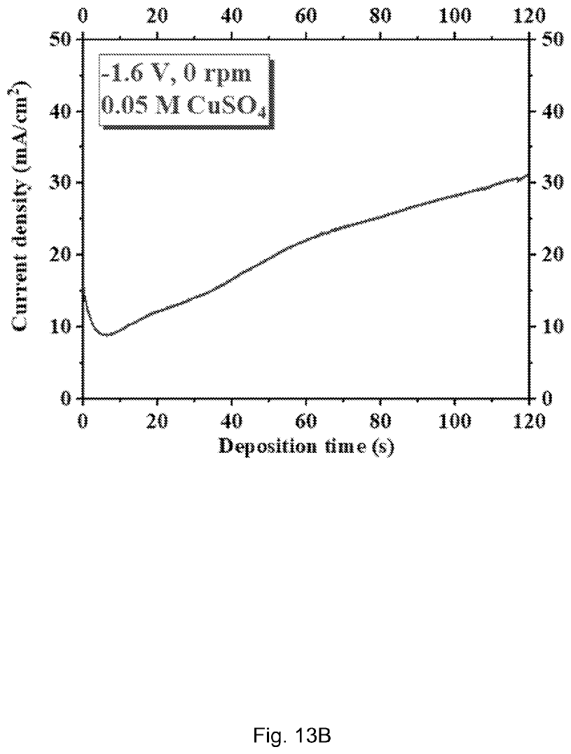

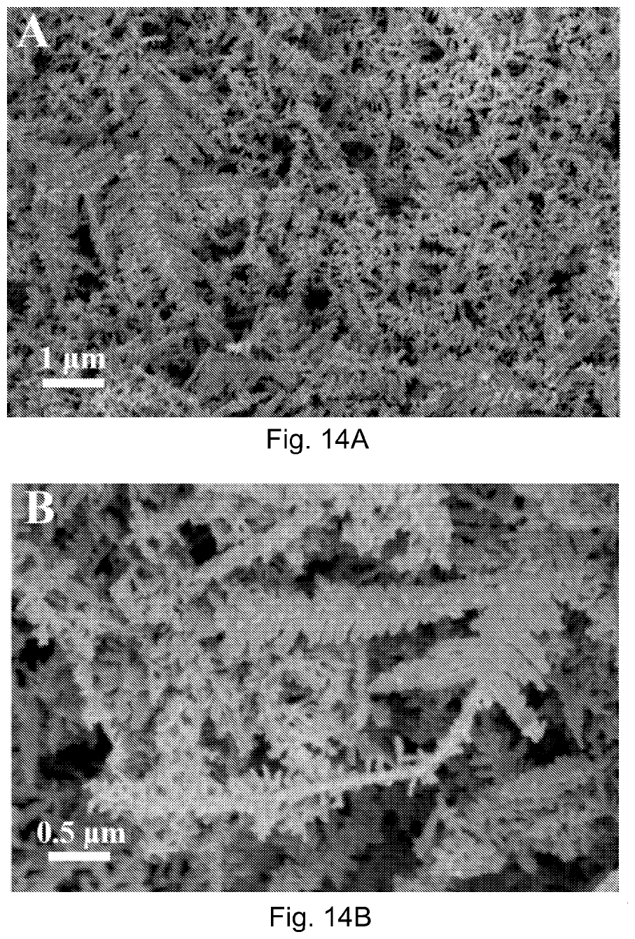

Considering that the analysis above does not involve the specific chemistry of Zn, e.g., its crystal structure, it was anticipated that analogous phenomena should be observable for other metals. To examine this, a comparative study of Cu electrodeposition in dilute (0.05M) and concentrated (1M) aqueous CuSO₄ electrolytes was performed. The selection of Cu deposition from CuSO₄ (aq) is mainly based on the following considerations: (a) both Zn and Cu do not form a passivating SEI like Li does that introduces additional complexity in ion transport; and (b) Zn and Cu have a hexagonal and a cubic crystal symmetry, respectively. Therefore, a comparison between them can rule out the possibility that the observed phenomenon, i.e., the suppression of dendritic growth in battery-concentration electrolyte, is specific to hexagonal metals, e.g., Zn. The results are shown in FIGS. 11-12 and their interpretation is straightforward—in 1M CuSO₄, tree-like Cu dendrites are not observed in the over-limiting regime; instead, similar to the Zn case, Cu deposits in high-porosity morphologies that again like Zn appear macroscopically homogeneous, suggesting that the deposition interface is stable. In contrast, the Cu deposits formed under over-limiting conditions in the dilute 0.05M CuSO₄ (aq) electrolyte exhibit obvious heterogeneous, dendritic morphology (FIGS. 13-14).

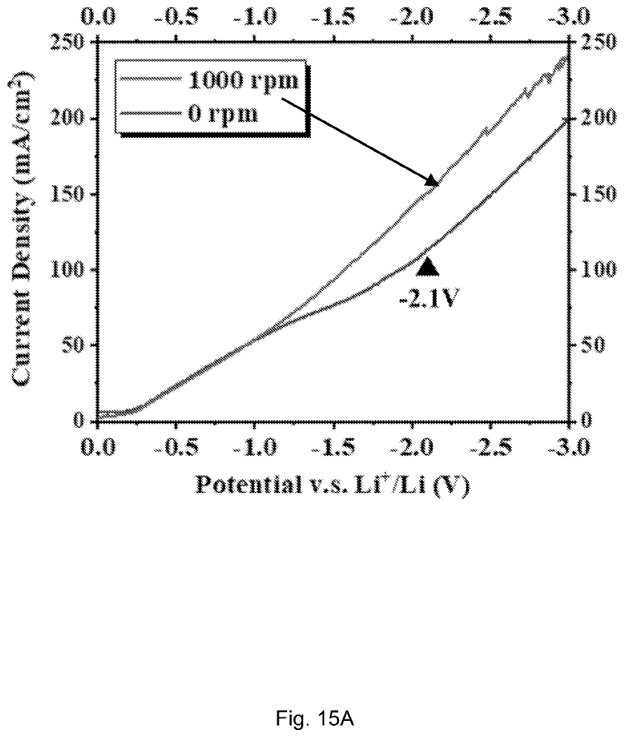

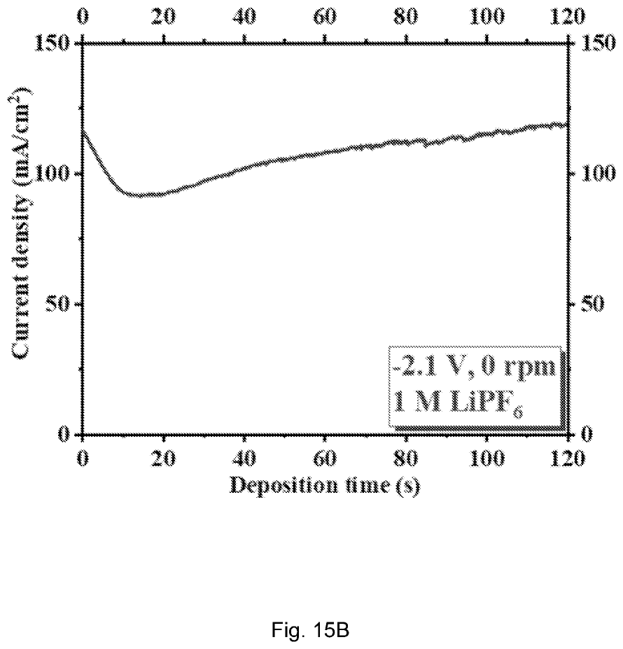

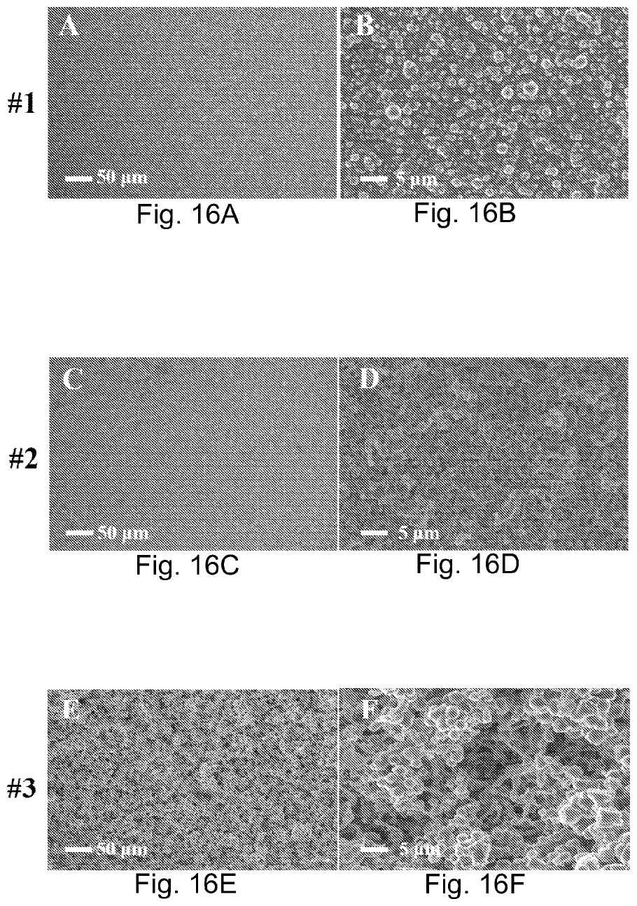

As a final question, it would be of broad interest to determine the relevance of these observations to other metals, including cubic Li, Na, K, Al and hexagonal Mg. It is noted that these metals also form solid-electrolyte interphases in liquid media, which is commonly thought to play a decisive role in their electrodeposition morphology. A preliminary assessment of Li electrodeposition in 1 M LiPF₆ in carbonate-based electrolyte is provided in FIGS. 15-16. Consistent with the results of Zn and Cu, no branched, tree-like dendritic structures are discernable in the moderately concentrated, 1 M electrolyte. Instead, highly porous, moss-like structures are formed, and the degree of porosity develops as the deposition condition moves from the below-limiting regime to the over limiting regime. Further exploration of the concept in the context of the electrodeposition of reactive metals that form SEI could be made with specific attention being paid to the potential influence of SEI on ion transport from the bulk electrolyte toward the deposition interface.

Materials and Methods. Materials. 0.25 mm Zn foil (99.9%), ZnSO₄·7H₂O and battery-grade 1M LiPF₆ dissolved in ethylene carbonate/dimethyl carbonate were purchased from Sigma Aldrich. 750 μm Li metal foil and CuSO₄·7H₂O was bought from Alfa Aesar. Cu foil was bought from MTI. Deionized water was obtained from Milli-Q water purification system. The resistivity of the deionized water is 18.2 MΩcm at room temperature.

Preparation of electrolytes. Zn electrolytes: ZnSO₄·7H₂O was dissolved into the deionized water to prepare the ZnSO₄ electrolytes for Zn electrodeposition. Cu electrolytes: CuSO₄·5H₂O was dissolved into the deionized water to prepare the CuSO₄ electrolyte for Cu electrodeposition. Li electrolyte: used as received from Sigma Aldrich (commercial battery-grade 1 M LiPF₆ in ethylene carbonate/dimethyl carbonate 1:1). All electrolytes were rested overnight before use.

Electrodeposition. The electrodeposition experiments in the present study were performed using a three-electrode system, including a working electrode made of glassy carbon, a counter electrode made of metal foils (Zn foil, Cu foil, or Li foil), and a reference electrode (AgCl/Ag for Zn and Cu deposition, Li foil for Li deposition). The substrate for metal electrodeposition (i.e., the working electrode) is glassy carbon electrode from Pine Research with a mirror polish finish achieved by submicron alumina powder. The rotating disk electrode (RDE) system was manufactured by Pine Research. During the electro-plating/stripping process, no bubbling is observable near the working electrode, which is attributable to the sluggish kinetics of H₂ evolution reaction (HER) in this system. After electrodeposition, the obtained deposits on the working electrode were washed by deionized water for 3 times before materials characterization. The deionized water was dripped to the electrode surface by pipette slowly. For Li deposition, the apparatus was moved into Ar-filled glovebox to protect Li and the electrolyte against oxidants and moisture. The Li electrodeposits were washed by pure dimethyl carbonate. The samples were transferred into microscope under Ar gas protection.

Characterization of materials. Field-emission scanning electron microscopy (FESEM) was carried out on Zeiss Gemini 500 Scanning Electron Microscope. Linear sweep voltammetry and chronoamperometry was performed using a CH 600E electrochemical workstation. 2D X-ray diffraction was performed on Bruker D8 General Area Detector Diffraction System with a Cu Kα X-ray source.

Coulombic efficiency measurement. Chronoamperometric plating/stripping of metals were conducted on glassy carbon electrode using three-electrode configuration. The metal plating/stripping

$$Coulombic efficiency ( C E ) = \frac{stripping capacity}{plating capacity on the substrate} \times 100 \% ,$$

which quantifies the reversibility of the metal anode. For example, CE=100% means all the plated Zn on the substrate can be stripped; while CE=80% means that 80% of plated Zn can be stripped and 20% Zn is electrochemically inactive.

Although the present disclosure has been described with respect to one or more particular examples, it will be understood that other examples of the present disclosure may be made without departing from the scope of the present disclosure.

1. An anode comprising:
a metal member; and
an epitaxial metal conducting coating disposed on at least a portion of the metal member.

2. The anode of claim 1, wherein the metal conducting coating epitaxially templates deposition of the reduced form of the metal-ions of a metal ion-conducting electrochemical device.

3. The anode of claim 1, wherein the metal conducting coating comprises a metal chosen from lithium, sodium, potassium, calcium, magnesium, zinc, aluminum, and iron.

4. The anode of claim 1, wherein the metal conducting coating comprises a metal chosen from gold, silver, zirconium, titanium, iron, copper, and chromium or a metal alloy chosen from combinations of gold, silver, zirconium, titanium, iron, copper, and chromium.

5. The anode of claim 1, wherein the metal conducting coating is crystalline.

6. The anode of claim 1, wherein at least a portion or all of an exterior surface of the metal conducting coating have crystal facets.

7. The anode of claim 1, wherein the crystal facets are chosen from a (001) plane in hexagonal closest packed structure, a (111) plane in face-centered cubic structures, and a (110) plane in body-centered cubic structures.

8. The anode of claim 1, wherein the thickness of the metal conducting coating is from a monolayer up to and including 500 micrometers.

9. The anode of claim 1, wherein the metal conducting coating has a conductivity of 10¹ to 10⁹ S/m.

10. The anode of claim 1, wherein the metal conducting coating is deposited by electrochemical deposition and the metal conducting coating is subjected to a field during deposition.

11. A device comprising one or more anode(s) of claim 1.

12. The device of claim 11, wherein the device is an electrochemical device.

13. The device of claim 12, wherein the electrochemical device is a battery, a supercapacitor, a fuel cell, an electrolyzer, or an electrolytic cell.

14. The device of claim 13, wherein the battery is an ion-conducting battery.

15. The device of claim 14, wherein the ion-conducting battery is a lithium-ion conducting battery, a potassium-ion conducting battery, a sodium-ion conducting battery, a calcium-ion conducting battery, a magnesium-ion conducting battery, a zinc-ion conducting battery, an aluminum-ion conducting battery, or an iron-ion conducting battery.

16. The device of claim 11, wherein the device is configured so that the conducting metal ions electrodeposit on at least a portion or all of the surface of the conducting coating in contact with the electrolyte forming an electrochemically deposited metal layer comprising one or more crystalline domain(s) or a crystalline metal layer.

17. The device of claim 16, wherein the electrochemically deposited metal layer has substantially bulk metal density.

18. The device of claim 16, wherein the electrochemically deposited metal layer comprises a plurality of metal layers.

19. The device of claim 13, wherein the battery exhibits one or more or all of the following:
the battery does not exhibit detectible dendritic growth and/or orphaning,
a plating and/or stripping Coulombic efficiency of 95% or greater, 98% or greater, 99% or greater, or 99.5% or greater,
a plating and/or stripping Coulombic efficiency of 95% or greater, 98% or greater, 99% or greater, or 99.5% or greater for 10,000 cycles or greater and/or at rate of 40 mA/cm² or greater.

20. A method of making a metal conducting coating disposed on at least a portion of an exterior surface of a substrate comprising:
electrodepositing a metal layer on at least a portion of an exterior surface of a substrate in the presence of a field,
wherein a metal conducting coating disposed on at least a portion of an exterior surface of a substrate is formed.

21. The method of claim 20, wherein the field is a hydrodynamic field.

22. The method of claim 21, wherein the hydrodynamic field is generated by a mechanical force, an electric force, a magnetic force, or a combination thereof.

23. The method of claim 21, wherein the hydrodynamic field is produced by rotating the substrate; flow imposed by an external stirring device; application of an orthogonal magnetic field to ions moving in an electrolyte; magnetically rotated micro-/nano structures dispersed in an electrolyte; or programmed periodic squeezing of a battery pouch cell.

24. The method of claim 23, wherein the substrate is rotating such that the rate of the electrochemical deposition exceeds the mass transfer limit of the electrodeposition.

25. The method of claim 20, wherein the field comprises a component normal to the deposition substrate.

26. The method of claim 20, wherein the electrodeposition is carried out in an electrolyte solution.

27. The method of claim 26, wherein the electrodeposition electrolyte solution comprises one or more metal salt(s).

28. The method of claim 20, wherein the electrodeposition is carried out in an inert atmosphere.

29. The method of claim 21, wherein the hydrodynamic field results in formation of an at least partially aligned metal layer.

30. The method of claim 29, wherein the metal of the at least partially aligned metal layer comprises hexagonal crystalline domains, cubic crystalline domains, tetragonal crystalline domains, orthorhombic crystalline domains, monoclinic crystalline domains, triclinic crystalline domains, or the like, or a combination thereof.

31. The method of claim 29, wherein the at least partially aligned metal layer comprises a plurality of the metal platelets.

32. The method of claim 29, wherein the at least partially aligned metal layer has a thickness of 10 micrometers to 1 centimeter.

33. The method of claim 20, wherein the substrate is chosen from metals and metal alloys.

34. An electrochemical device configured to provide a field that results in formation of one or more metal conducing coating(s) and/or one or more anode(s) of claim 1.

35. An electrochemical device configured to carry out a method of claim 20.
